(19) United States
(12) Patent Application Publication
(10) Pub. No.: US 2007/0134511 A1
(43) Pub. Date: Jun. 14, 2007

(54) Organic electroluminescence device

(75) Inventors: Hisayuki Kawamura, Sodegaura-shi (JP); Mineyuki Kubota, Sodegaura-shi (JP)

Correspondence Address: STEPTOE & JOHNSON LLP, 1330 CONNECTICUT AVENUE, N.W., WASHINGTON, DC, 20036, US

(73) Assignee: Idemitsu Kosan Co., LTD., Chiyoda-ku (JP)

(21) Appl. No.: 11/296,400

(22) Filed: Dec. 8, 2005

(30) Foreign Application Priority Data
Dec. 8, 2005 (JP) 2004-355344

(51) Int. Cl. H01L 51/54

(52) U.S. Cl. 428/690; 428/917; 313/504; 257/40; 257/E51.051; 257/E51.049; 564/427; 564/434

(57) ABSTRACT

An organic electroluminescent device including a pair of electrodes and an emitting layer provided between the pair of electrodes, the emitting layer comprising a derivative having an unsymmetrically substituted anthracene as a partial structure and an amine derivative represented by Formula (1), 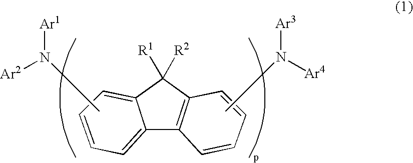
wherein Ar¹ to Ar⁴ are independently a substituted or unsubstituted aromatic ring having 6 to 50 nucleus carbon atoms, R¹ and R² may be the same or different substituents and linked to each other to form a saturated or unsaturated ring, and p is an integer of 1 to 6.

### TECHNICAL FIELD

The invention relates to an organic electroluminescent device (organic EL device), particularly an organic EL device emitting blue light.

### Background Art

An organic EL device is a self-emission device by the use of the principle that a fluorescent compound emits light by the recombination energy of holes injected from an anode and electrons injected from a cathode when an electric field is applied. Since C. W. Tang et al. of Eastman Kodak Co. reported a low-voltage driven organic EL device in the form of a stacked type device (C. W. Tang, S. A. Vanslyke, Applied Physics Letters, Vol. 51, p. 913, 1987, and the like), studies on organic EL devices wherein organic materials are used as the constitution materials has actively conducted.

Tang et al. uses tris(8-hydroxyquinolinol aluminum) for an emitting layer and a triphenyldiamine derivative for a hole-transporting layer in the stacked structure. The advantages of the stacked structure are to increase injection efficiency of holes to the emitting layer, to increase generation efficiency of excitons generated by recombination while blocking electrons injected from the cathode, to contain the excitons generated in the emitting layer, and so on. Like this example, as the device structure of the organic EL device, a two-layered type of a hole-transporting (injecting) layer and an electron-transporting emitting layer, and a three-layered type of a hole-transporting (injecting) layer, an emitting layer and an electron-transporting (injecting) layer are widely known. In such stacked structure devices, the device structures and the fabrication methods have been contrived to increase recombination efficiency of injected holes and electrons.

As emitting materials, chelate complexes such as tris(8-quinolilatoquinolylate)aluminum complex, coumarin derivatives, tetraphenylbutadiene derivatives, bisstyrylarylene derivatives, oxadiazole derivatives, and the like are known. It was reported that by using these materials, emission in visible region of from blue to red can be obtained, and realization of a color display device is expected (for example, Patent Documents 1, 2, 3 and the like).

Furthermore, various improvements are made to emitting materials, and for instance, a device using a bisanthracene derivative as an emitting material (Patent Documents 4 and 5). The bisanthracene derivatives are used as a blue emitting material, but the emission efficiency and lifetime did not reach the level for practical use, it being insufficient.

Also, a device using a symmetrical pyrene derivative as the emitting material is disclosed in Patent Documents 6, 7, 8 and 9, and a device using a condensed ring-containing compound in Patent Documents 10 and 11. Such a symmetrical pyrene derivative and condensed ring-containing compound are used as a blue emitting material, and improvement in lifetime has been sought for. In particular, Patent Document 11 discloses a device structure wherein a specific pyrene trimer is doped with a condensed aromatic amine. However, this device has short lifetime and is liable to be thermally decomposed upon deposition, and thus, is unfitted to mass production.

A device structure wherein a host of an anthracene derivative is doped with a condensed aromatic amine (Patent Document 12) and a device structure wherein a specific pyrene dimer is doped with a diaminofluorene derivative (Patent Document 13) are proposed. However, there is a problem that these devices have short lifetime.

Patent Document 1: JP-A-H8-239655

Patent Document 2: JP-A-H7-183561

Patent Document 3: JP-A-H3-200289

Patent Document 4: USP 3008897

Patent Document 5: JP-A-H8-12600

Patent Document 6: JP-A-2001-118682

Patent Document 7: JP-A-2002-63988

Patent Document 8: JP-A-2004-75567

Patent Document 9: JP-A-2004-83481

Patent Document 10: JP-A-2002-50481

Patent Document 11: JP-A-2002-324678

Patent Document 12: WO 04/18588

Patent Document 13: JP-A-2004-002298

An object of the invention is to provide an organic EL device with a long lifetime in view of the above-mentioned problems.

Through research for achieving the object, the inventors found that an organic EL device containing a certain arylene derivative and a certain amine derivative has a long lifetime and completed the invention.

### DISCLOSURE OF THE INVENTION

According to the invention, the following organic EL device is provided.
1. An organic electroluminescent device comprising a pair of electrodes and an emitting layer provided between the pair of electrodes,

the emitting layer comprising a derivative having an unsymmetrically substituted anthracene as a partial structure and an amine derivative represented by Formula (1), 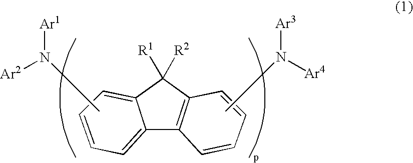
wherein Ar¹ to Ar⁴ are independently a substituted or unsubstituted aromatic ring having 6 to 50 nucleus carbon atoms, R¹ and R² may be the same or different substituents and linked to each other to form a saturated or unsaturated ring, and p is an integer of 1 to 6.
2. An organic electroluminescent device comprising a pair of electrodes and an emitting layer provided between the pair of electrodes,

the emitting layer comprising a derivative having an unsymmetrically substituted pyrene as a partial structure, the number of pyrene skeleton contained in the derivative being one, and an amine derivative represented by Formula (1), 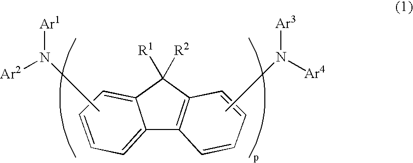
wherein Ar¹ to Ar⁴ are independently a substituted or unsubstituted aromatic ring having 6 to 50 nucleus carbon atoms, R¹ and R² may be the same or different substituents and linked to each other to form a saturated or unsaturated ring, and p is an integer of 1 to 6.
3. The organic electroluminescent device according to 1 or 2, wherein the amine derivative is a diaminofluorene derivative where R¹ and R² are linked to each other to form a saturated or unsaturated ring in Formula (1).
4. The organic electroluminescent device according to any one of 1 to 3, wherein the amine derivative is contained in an amount of 0.1 to 20 mol % in the emitting layer.

The invention can provide an organic EL device with a long lifetime.

### BEST MODES FOR CARRYING OUT THE INVENTION

An organic EL device of the invention includes at least an emitting layer provided between a pair of electrodes, and the emitting layer contains a derivative having an unsymmetrically substituted anthracene as a partial structure (hereinafter referred to as an unsymmetric anthracene derivative) and an amine derivative represented by Formula (1).

The organic EL device of the invention includes at least an emitting layer provided between a pair of electrodes, and the emitting layer contains a derivative having an unsymmetrically substituted pyrene as a partial structure, the number of pyrene skeleton contained in the derivative being one, (hereinafter referred to as an unsymmetric pyrene derivative) and an amine derivative represented by formula (1).

First, the unsymmetric anthracene derivative or the unsymmetric pyrene derivative will be described. As an unsymmetric anthracene derivative, the compounds represented by Formula (2) below can be exemplified. 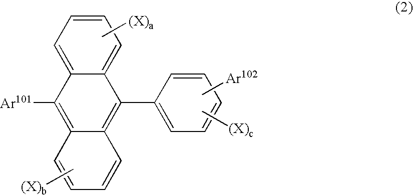
wherein Ar¹⁰¹ is a substituted or unsubstituted condensed aromatic group having 10 to 50 nucleus carbon atoms,

Ar¹⁰² is a substituted or unsubstituted aromatic group having 6 to 50 nucleus carbon atoms,

X is a substituted or unsubstituted aromatic group having 6 to 50 nucleus carbon atoms, a substituted or unsubstituted aromatic heterocyclic group having 5 to 50 nucleus carbon atoms, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 nucleus carbon atoms, a substituted or unsubstituted arylthio group having 5 to 50 nucleus carbon atoms, a substituted or unsubstituted alkoxycarbonyl group having 1 to 50 carbon atoms, a carboxyl group, a halogen atom, a cyano group, a nitro group or a hydroxyl group.

a, b and c are each an integer of 0 to 4.

Preferably, Ar¹⁰¹ or Ar¹⁰² is a group selected from the formulas below. 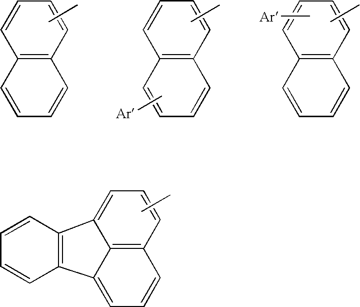
wherein Ar′ is a substituted or unsubstituted aromatic group having 6 to 50 nucleus carbon atoms.

More preferably, Ar¹⁰¹ or Ar¹⁰² is naphthyl.

a, b and c are preferably 1, and more preferably 0.

Specific compounds are shown below.

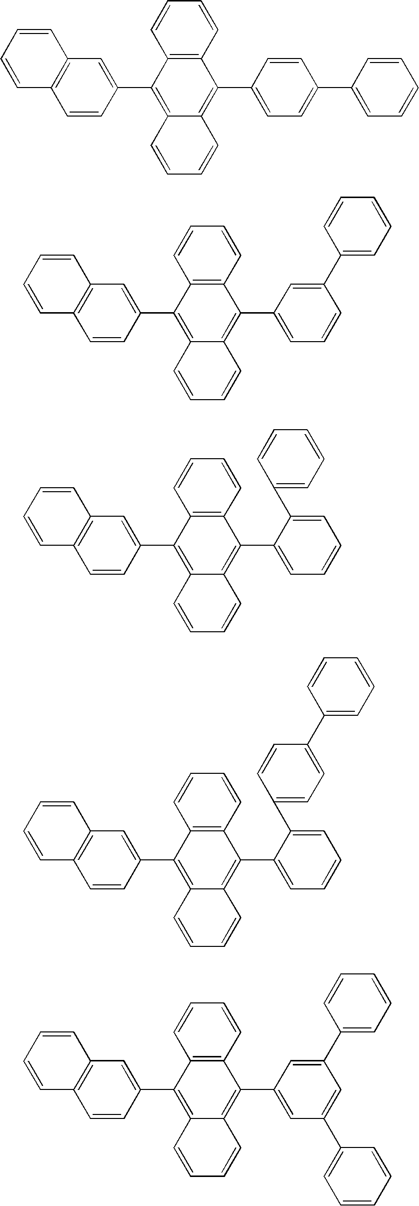

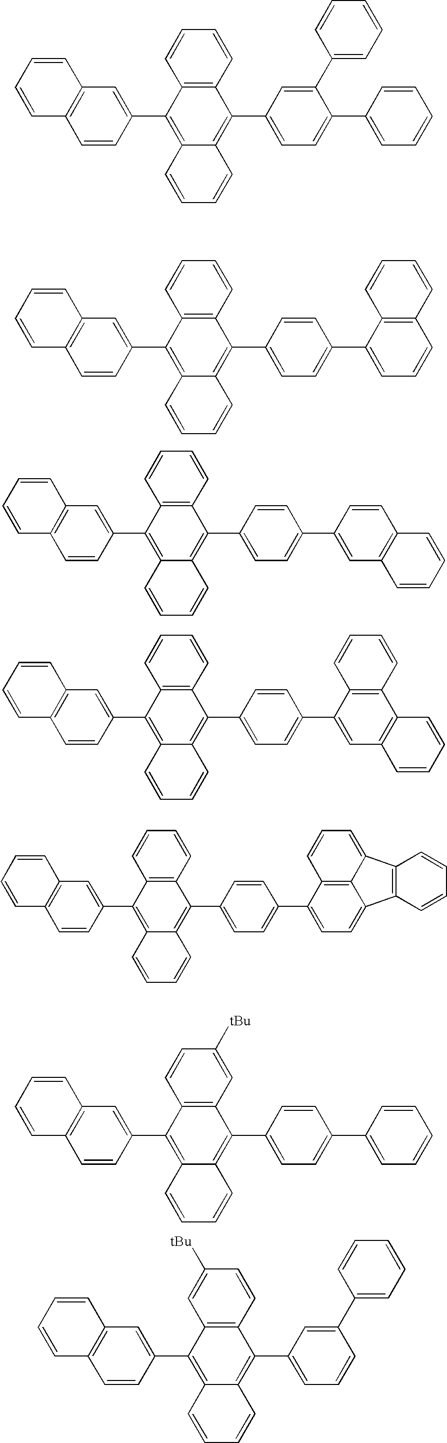

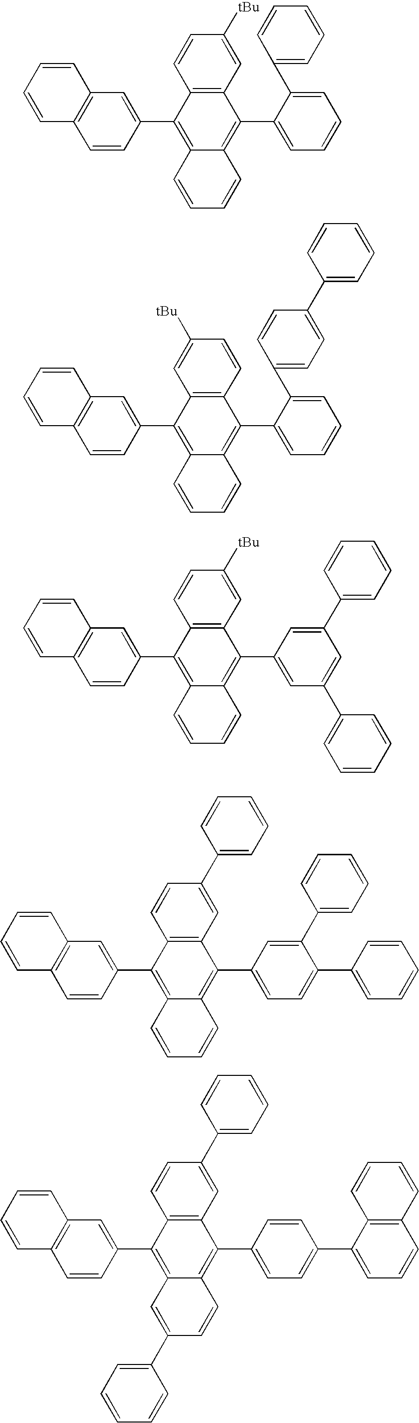

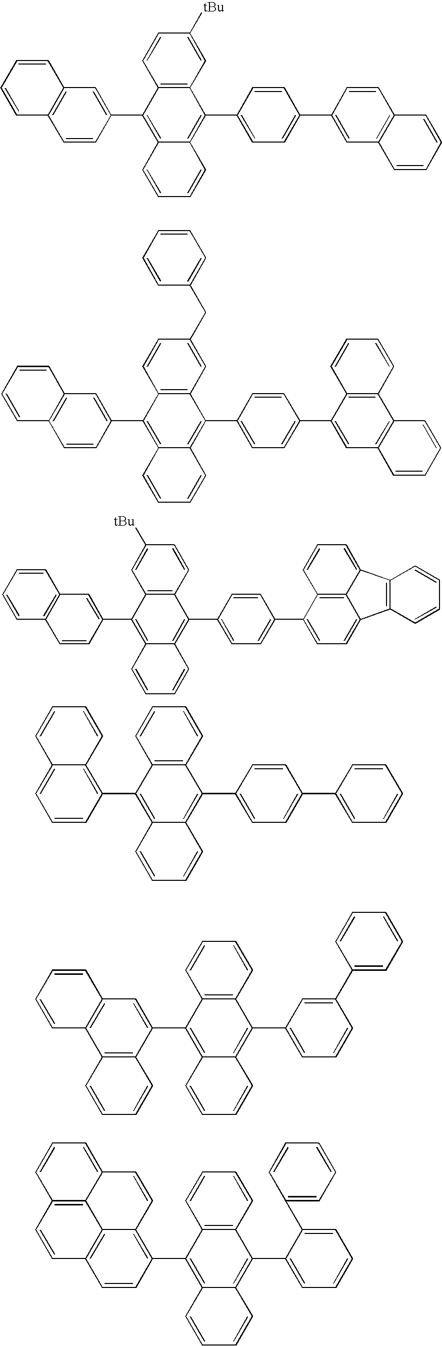

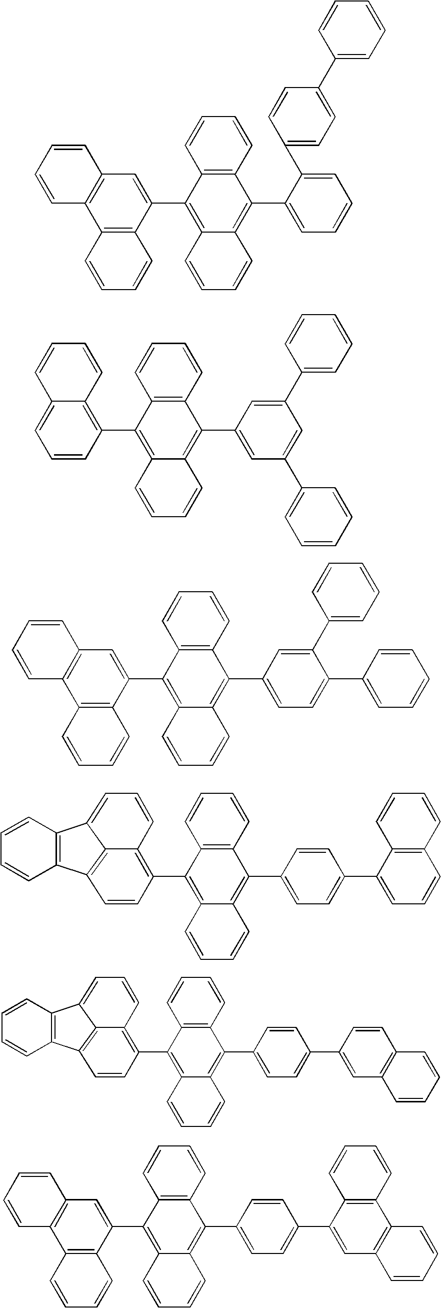

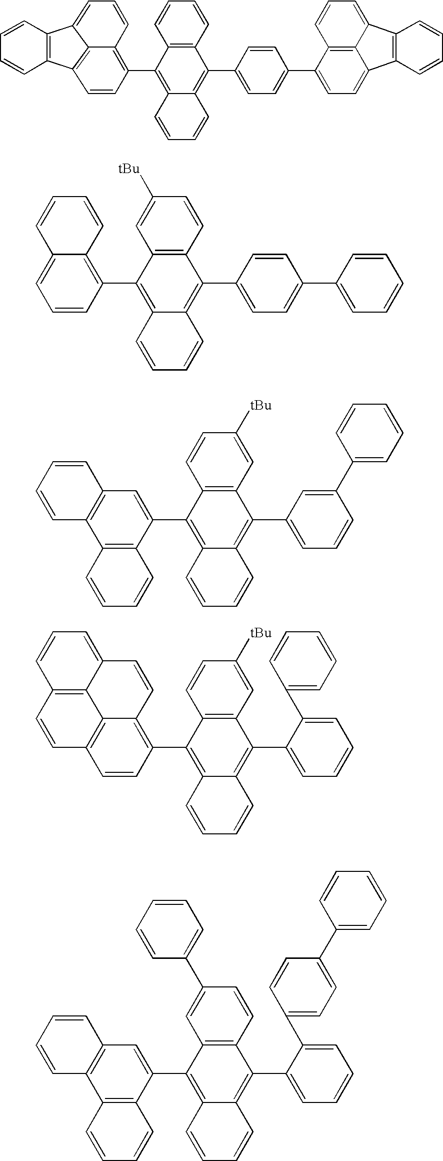

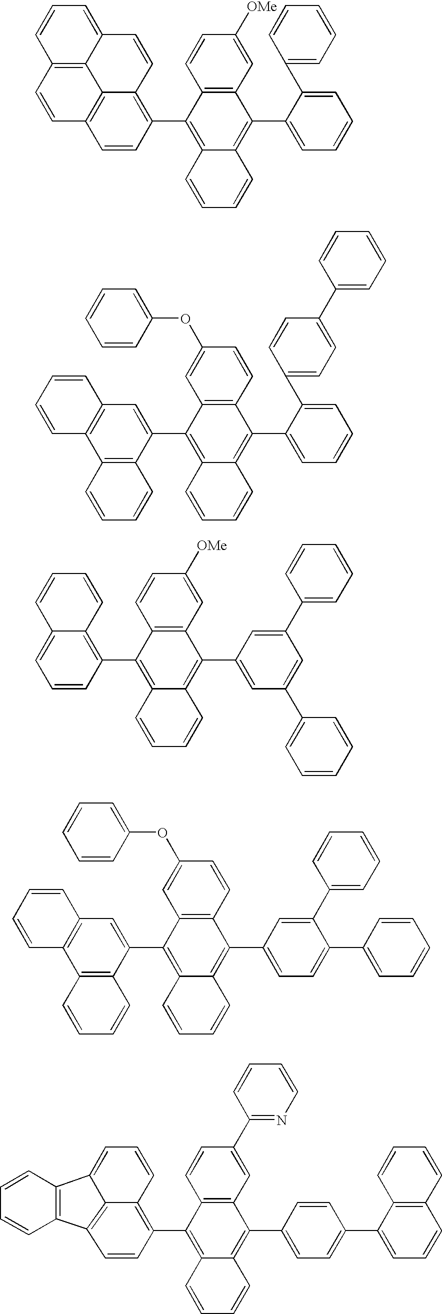

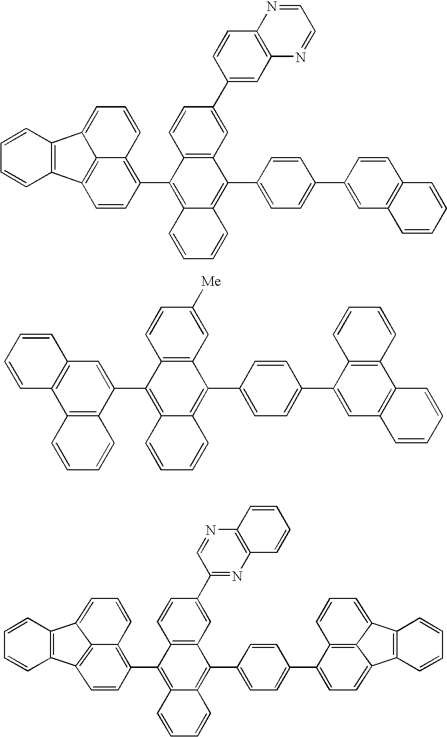

As an unsymmetric anthracene derivative, the compounds represented by Formula (3) below can be exemplified. 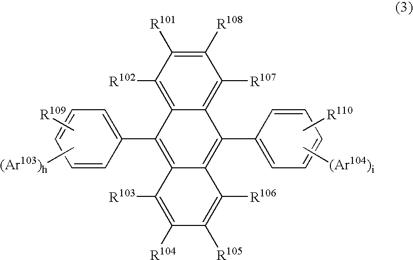
wherein Ar¹⁰³ and Ar¹⁰⁴ are independently a substituted or unsubstituted aromatic ring group having 6 to 50 nucleus carbon atoms, and h and i are each an integer of 1 to 4, provided that when h=i=1 and the bonding positions to benzene rings of Ar¹⁰³ and Ar¹⁰⁴ are symmetric, Ar¹⁰³ and Ar¹⁰⁴ are not the same, and when h or i is an integer of 2 to 4, h and i are different integers,

R¹⁰¹ to R¹¹⁰ are independently a hydrogen atom, a substituted or unsubstituted aromatic ring group having 6 to 50 nucleus carbon atoms, a substituted or unsubstituted aromatic heterocyclic ring group having 5 to 50 nucleus carbon atoms, a substituted or unsubstituted alkyl group having 1 to 50 carbon atoms, a substituted or unsubstituted cycloalkyl group, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 nucleus carbon atoms, a substituted or unsubstituted arylthio group having 5 to 50 nucleus carbon atoms, a substituted or unsubstituted alkoxycarbonyl group having 1 to 50 carbon atoms, a substituted or unsubstituted silyl group, a carboxyl group, a halogen atom, a cyano group, a nitro group or a hydroxyl group.

Specific compounds are shown below.

| | | |
|---|---|---|
| Compound | Ar¹⁰³ | Ar¹⁰⁴ |

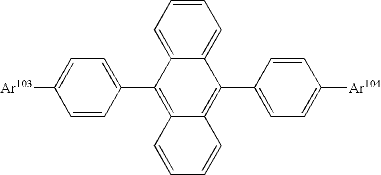

| | | |
|---|---|---|
| AN-1 | 1-naphthyl | 9-phenanthryl |
| AN-2 | 1-naphthyl | 1-pyrenyl |
| AN-3 | 1-naphthyl | phenyl |
| AN-4 | 1-naphthyl | 2-biphenyl |
| AN-5 | 1-naphthyl | 3-biphenyl |
| AN-6 | 1-naphthyl | 4-biphenyl |
| AN-7 | 1-naphthyl | 2-p-terphenyl |
| AN-8 | 2-naphthyl | 1-naphthyl |
| AN-9 | 2-naphthyl | 9-phenanthryl |
| AN-10 | 2-naphthyl | 1-pyrenyl |
| AN-11 | 2-naphthyl | phenyl |
| AN-12 | 2-naphthyl | 2-biphenyl |
| AN-13 | 2-naphthyl | 3-biphenyl |
| AN-14 | 2-naphthyl | 4-biphenyl |
| AN-15 | 2-naphthyl | 2-p-terphenyl |
| AN-16 | 9-phenanthryl | 1-pyrenyl |
| AN-17 | 9-phenanthryl | phenyl |
| AN-18 | 9-phenanthryl | 2-biphenyl |
| AN-19 | 9-phenanthryl | 3-biphenyl |
| AN-20 | 9-phenanthryl | 4-biphenyl |
| AN-21 | 9-phenanthryl | 2-p-terphenyl |
| AN-22 | 1-pyrenyl | phenyl |
| AN-23 | 1-pyrenyl | 2-biphenyl |
| AN-24 | 1-pyrenyl | 3-biphenyl |
| AN-25 | 1-pyrenyl | 4-biphenyl |
| AN-26 | 1-pyrenyl | 2-p-terphenyl |
| AN-27 | phenyl | 2-biphenyl |
| AN-28 | phenyl | 3-biphenyl |
| AN-29 | phenyl | 4-biphenyl |
| AN-30 | phenyl | 2-p-terphenyl |
| AN-31 | 2-biphenyl | 3-biphenyl |
| AN-32 | 2-biphenyl | 4-biphenyl |
| AN-33 | 2-biphenyl | 2-p-terphenyl |
| AN-34 | 3-biphenyl | 4-biphenyl |
| AN-35 | 3-biphenyl | 2-p-terphenyl |

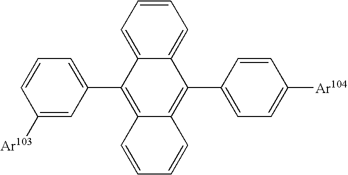

| | | |
|---|---|---|
| AN-36 | 1-naphthyl | 1-naphthyl |
| AN-37 | 1-naphthyl | 2-naphthyl |
| AN-38 | 1-naphthyl | 9-phenanthryl |
| AN-39 | 1-naphthyl | 1-pyrenyl |
| AN-40 | 1-naphthyl | phenyl |
| AN-41 | 1-naphthyl | 2-biphenyl |
| AN-42 | 1-naphthyl | 3-biphenyl |
| AN-43 | 1-naphthyl | 4-biphenyl |
| AN-44 | 1-naphthyl | 2-p-terphenyl |
| AN-45 | 2-naphthyl | 1-naphthyl |
| AN-46 | 2-naphthyl | 2-naphthyl |
| AN-47 | 2-naphthyl | 9-phenanthryl |
| AN-48 | 2-naphthyl | 1-pyrenyl |
| AN-49 | 2-naphthyl | phenyl |
| AN-50 | 2-naphthyl | 2-biphenyl |
| AN-51 | 2-naphthyl | 3-biphenyl |
| AN-52 | 2-naphthyl | 4-biphenyl |
| AN-53 | 2-naphthyl | 2-p-terphenyl |
| AN-54 | 9-phenanthryl | 1-naphthyl |
| AN-55 | 9-phenanthryl | 2-naphthyl |
| AN-56 | 9-phenanthryl | 9-phenanthryl |
| AN-57 | 9-phenanthryl | 1-pyrenyl |
| AN-58 | 9-phenanthryl | phenyl |
| AN-59 | 9-phenanthryl | 2-biphenyl |
| AN-60 | 9-phenanthryl | 3-biphenyl |
| AN-61 | 9-phenanthryl | 4-biphenyl |
| AN-62 | 9-phenanthryl | 2-p-terphenyl |
| AN-63 | 1-pyrenyl | 1-naphthyl |
| AN-64 | 1-pyrenyl | 2-naphthyl |
| AN-65 | 1-pyrenyl | 9-phenanthryl |
| AN-67 | 1-pyrenyl | phenyl |
| AN-68 | 1-pyrenyl | 2-biphenyl |
| AN-69 | 1-pyrenyl | 3-biphenyl |
| AN-70 | 1-pyrenyl | 4-biphenyl |
| AN-71 | 1-pyrenyl | 2-p-terphenyl |
| AN-72 | phenyl | 1-naphthyl |
| AN-73 | phenyl | 2-naphthyl |
| AN-74 | phenyl | 9-phenanthryl |
| AN-75 | phenyl | 1-pyrenyl |
| AN-76 | phenyl | phenyl |
| AN-77 | phenyl | 2-biphenyl |
| AN-78 | phenyl | 3-biphenyl |
| AN-79 | phenyl | 4-biphenyl |
| AN-80 | phenyl | 2-p-terphenyl |
| AN-81 | 2-biphenyl | 1-naphthyl |
| AN-82 | 2-biphenyl | 2-naphthyl |
| AN-83 | 2-biphenyl | 9-phenanthryl |
| AN-84 | 2-biphenyl | 1-pyrenyl |
| AN-85 | 2-biphenyl | phenyl |
| AN-86 | 2-biphenyl | 2-biphenyl |
| AN-87 | 2-biphenyl | 3-biphenyl |
| AN-88 | 2-biphenyl | 4-biphenyl |
| AN-89 | 2-biphenyl | 2-p-terphenyl |
| AN-90 | 3-biphenyl | 1-naphthyl |
| AN-91 | 3-biphenyl | 2-naphthyl |
| AN-92 | 3-biphenyl | 9-phenanthryl |
| AN-93 | 3-biphenyl | 1-pyrenyl |
| AN-94 | 3-biphenyl | phenyl |
| AN-95 | 3-biphenyl | 2-biphenyl |
| AN-96 | 3-biphenyl | 3-biphenyl |
| AN-97 | 3-biphenyl | 4-biphenyl |
| AN-98 | 3-biphenyl | 2-p-terphenyl |
| AN-99 | 4-biphenyl | 1-naphthyl |
| AN-100 | 4-biphenyl | 2-naphthyl |
| AN-101 | 4-biphenyl | 9-phenanthryl |
| AN-102 | 4-biphenyl | 1-pyrenyl |
| AN-103 | 4-biphenyl | phenyl |
| AN-104 | 4-biphenyl | 2-biphenyl |
| AN-105 | 4-biphenyl | 3-biphenyl |
| AN-106 | 4-biphenyl | 4-biphenyl |
| AN-107 | 4-biphenyl | 2-p-terphenyl |

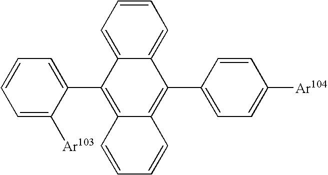

| | | |
|---|---|---|
| AN-108 | 1-naphthyl | 1-naphthyl |
| AN-109 | 1-naphthyl | 2-naphthyl |
| AN-110 | 1-naphthyl | 9-phenanthryl |
| AN-111 | 1-naphthyl | 1-pyrenyl |
| AN-112 | 1-naphthyl | phenyl |
| AN-113 | 1-naphthyl | 2-biphenyl |
| AN-114 | 1-naphthyl | 3-biphenyl |
| AN-115 | 1-naphthyl | 4-biphenyl |
| AN-116 | 1-naphthyl | 2-p-terphenyl |
| AN-117 | 2-naphthyl | 1-naphthyl |
| AN-118 | 2-naphthyl | 2-naphthyl |
| AN-119 | 2-naphthyl | 9-phenanthryl |
| AN-120 | 2-naphthyl | 1-pyrenyl |
| AN-121 | 2-naphthyl | phenyl |
| AN-122 | 2-naphthyl | 2-biphenyl |
| AN-123 | 2-naphthyl | 3-biphenyl |
| AN-124 | 2-naphthyl | 4-biphenyl |
| AN-125 | 2-naphthyl | 2-p-terphenyl |
| AN-126 | 9-phenanthryl | 1-naphthyl |
| AN-127 | 9-phenanthryl | 2-naphthyl |
| AN-128 | 9-phenanthryl | 9-phenanthryl |
| AN-129 | 9-phenanthryl | 1-pyrenyl |
| AN-130 | 9-phenanthryl | phenyl |
| AN-131 | 9-phenanthryl | 2-biphenyl |
| AN-132 | 9-phenanthryl | 3-biphenyl |
| AN-133 | 9-phenanthryl | 4-biphenyl |
| AN-134 | 9-phenanthryl | 2-p-terphenyl |
| AN-135 | 1-pyrenyl | 1-naphthyl |
| AN-136 | 1-pyrenyl | 2-naphthyl |
| AN-137 | 1-pyrenyl | 9-phenanthryl |
| AN-139 | 1-pyrenyl | phenyl |
| AN-140 | 1-pyrenyl | 2-biphenyl |
| AN-141 | 1-pyrenyl | 3-biphenyl |
| AN-142 | 1-pyrenyl | 4-biphenyl |
| AN-143 | 1-pyrenyl | 2-p-terphenyl |
| AN-144 | phenyl | 1-naphthyl |
| AN-145 | phenyl | 2-naphthyl |
| AN-146 | phenyl | 9-phenanthryl |
| AN-147 | phenyl | 1-pyrenyl |
| AN-148 | phenyl | phenyl |
| AN-149 | phenyl | 2-biphenyl |
| AN-150 | phenyl | 3-biphenyl |
| AN-151 | phenyl | 4-biphenyl |
| AN-152 | phenyl | 2-p-terphenyl |
| AN-153 | 2-biphenyl | 1-naphthyl |
| AN-154 | 2-biphenyl | 2-naphthyl |
| AN-155 | 2-biphenyl | 9-phenanthryl |
| AN-156 | 2-biphenyl | 1-pyrenyl |
| AN-157 | 2-biphenyl | phenyl |
| AN-158 | 2-biphenyl | 2-biphenyl |
| AN-159 | 2-biphenyl | 3-biphenyl |
| AN-160 | 2-biphenyl | 4-biphenyl |
| AN-161 | 2-biphenyl | 2-p-terphenyl |
| AN-162 | 3-biphenyl | 1-naphthyl |
| AN-163 | 3-biphenyl | 2-naphthyl |
| AN-164 | 3-biphenyl | 9-phenanthryl |
| AN-165 | 3-biphenyl | 1-pyrenyl |
| AN-166 | 3-biphenyl | phenyl |
| AN-167 | 3-biphenyl | 2-biphenyl |
| AN-168 | 3-biphenyl | 3-biphenyl |
| AN-169 | 3-biphenyl | 4-biphenyl |
| AN-170 | 3-biphenyl | 2-p-terphenyl |
| AN-171 | 4-biphenyl | 1-naphthyl |
| AN-172 | 4-biphenyl | 2-naphthyl |
| AN-173 | 4-biphenyl | 9-phenanthryl |
| AN-174 | 4-biphenyl | 1-pyrenyl |
| AN-175 | 4-biphenyl | phenyl |
| AN-176 | 4-biphenyl | 2-biphenyl |
| AN-177 | 4-biphenyl | 3-biphenyl |
| AN-178 | 4-biphenyl | 4-biphenyl |
| AN-179 | 4-biphenyl | 2-p-terphenyl |

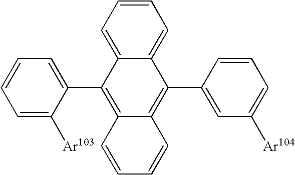

| | | |
|---|---|---|
| AN-180 | 1-naphthyl | 1-naphthyl |
| AN-181 | 1-naphthyl | 2-naphthyl |
| AN-182 | 1-naphthyl | 9-phenanthryl |
| AN-183 | 1-naphthyl | 1-pyrenyl |
| AN-184 | 1-naphthyl | phenyl |
| AN-185 | 1-naphthyl | 2-biphenyl |
| AN-186 | 1-naphthyl | 3-biphenyl |
| AN-187 | 1-naphthyl | 4-biphenyl |
| AN-188 | 2-naphthyl | 1-naphthyl |
| AN-189 | 2-naphthyl | 2-naphthyl |
| AN-190 | 2-naphthyl | 9-phenanthryl |
| AN-191 | 2-naphthyl | 1-pyrenyl |
| AN-192 | 2-naphthyl | phenyl |
| AN-193 | 2-naphthyi | 2-biphenyl |
| AN-194 | 2-naphthyl | 3-biphenyl |
| AN-195 | 2-naphthyl | 4-biphenyl |
| AN-196 | 9-phenanthryl | 1-naphthyl |
| AN-197 | 9-phenanthryl | 2-naphthyl |
| AN-198 | 9-phenanthryl | 9-phenanthryl |
| AN-199 | 9-phenanthryl | 1-pyrenyl |
| AN-200 | 9-phenanthryl | phenyl |
| AN-201 | 9-phenanthryl | 2-biphenyl |
| AN-202 | 9-phenanthryl | 3-biphenyl |
| AN-203 | 9-phenanthryl | 4-biphenyl |
| AN-204 | 1-pyrenyl | 1-naphthyl |
| AN-205 | 1-pyrenyl | 2-naphthyl |
| AN-206 | 1-pyrenyl | 9-phenanthryl |
| AN-208 | 1-pyrenyl | phenyl |
| AN-209 | 1-pyrenyl | 2-biphenyl |
| AN-210 | 1-pyrenyl | 3-biphenyl |
| AN-211 | 1-pyrenyl | 4-biphenyl |
| AN-212 | phenyl | 1-naphthyl |
| AN-213 | phenyl | 2-naphthyl |
| AN-214 | phenyl | 9-phenanthryl |
| AN-215 | phenyl | 1-pyrenyl |
| AN-216 | phenyl | phenyl |
| AN-217 | phenyl | 2-biphenyl |
| AN-218 | phenyl | 3-biphenyl |
| AN-219 | phenyl | 4-biphenyl |
| AN-220 | 2-biphenyl | 1-naphthyl |
| AN-221 | 2-biphenyl | 2-naphthyl |
| AN-222 | 2-biphenyl | 9-phenanthryl |
| AN-223 | 2-biphenyl | 1-pyrenyl |
| AN-224 | 2-biphenyl | phenyl |
| AN-225 | 2-biphenyl | 2-biphenyl |
| AN-226 | 2-biphenyl | 3-biphenyl |
| AN-227 | 2-biphenyl | 4-biphenyl |
| AN-228 | 3-biphenyl | 1-naphthyl |
| AN-229 | 3-biphenyl | 2-naphthyl |
| AN-230 | 3-biphenyl | 9-phenanthryl |
| AN-231 | 3-biphenyl | 1-pyrenyl |
| AN-232 | 3-biphenyl | phenyl |
| AN-233 | 3-biphenyl | 2-biphenyl |
| AN-234 | 3-biphenyl | 3-biphenyl |
| AN-235 | 3-biphenyl | 4-biphenyl |
| AN-236 | 4-biphenyl | 1-naphthyl |
| AN-237 | 4-biphenyl | 2-naphthyl |
| AN-238 | 4-biphenyl | 9-phenanthryl |
| AN-239 | 4-biphenyl | 1-pyrenyl |
| AN-240 | 4-biphenyl | phenyl |
| AN-241 | 4-biphenyl | 2-biphenyl |
| AN-242 | 4-biphenyl | 3-biphenyl |
| AN-243 | 4-biphenyl | 4-biphenyl |

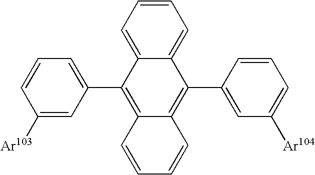

| | | |
|---|---|---|
| AN-244 | 1-naphthyl | 2-naphthyl |
| AN-245 | 1-naphthyl | 9-phenanthryl |
| AN-246 | 1-naphthyl | 1-pyrenyl |
| AN-247 | 1-naphthyl | phenyl |
| AN-248 | 1-naphthyl | 2-biphenyl |
| AN-249 | 1-naphthyl | 3-biphenyl |
| AN-250 | 1-naphthyl | 4-biphenyl |
| AN-251 | 2-naphthyl | 9-phenanthryl |
| AN-252 | 2-naphthyl | 1-pyrenyl |
| AN-253 | 2-naphthyl | phenyl |
| AN-254 | 2-naphthyl | 2-biphenyl |
| AN-255 | 2-naphthyl | 3-biphenyl |
| AN-256 | 2-naphthyl | 4-biphenyl |
| AN-257 | 9-phenanthryl | 1-pyrenyl |
| AN-258 | 9-phenanthryl | phenyl |
| AN-259 | 9-phenanthryl | 2-biphenyl |
| AN-260 | 9-phenanthryl | 3-biphenyl |
| AN-261 | 9-phenanthryl | 4-biphenyl |
| AN-262 | 1-pyrenyl | phenyl |
| AN-263 | 1-pyrenyl | 2-biphenyl |
| AN-264 | 1-pyrenyl | 3-biphenyl |
| AN-265 | 1-pyrenyl | 4-biphenyl |
| AN-266 | phenyl | 2-biphenyl |
| AN-267 | phenyl | 3-biphenyl |
| AN-268 | phenyl | 4-biphenyl |
| AN-269 | 2-biphenyl | 3-biphenyl |
| AN-270 | 2-biphenyl | 4-biphenyl |
| AN-271 | 3-biphenyl | 4-biphenyl |

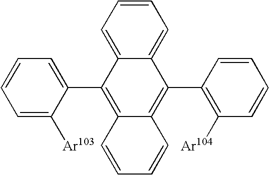

| | | |
|---|---|---|
| AN-272 | 1-naphthyl | 2-naphthyl |
| AN-273 | 1-naphthyl | 9-phenanthryl |
| AN-274 | 1-naphthyl | 1-pyrenyl |
| AN-275 | 1-naphthyl | phenyl |
| AN-276 | 1-naphthyl | 2-biphenyl |
| AN-277 | 1-naphthyl | 3-biphenyl |
| AN-278 | 1-naphthyl | 4-biphenyl |
| AN-279 | 2-naphthyl | 9-phenanthryl |
| AN-280 | 2-naphthyl | 1-pyrenyl |
| AN-281 | 2-naphthyl | phenyl |
| AN-282 | 2-naphthyl | 2-biphenyl |
| AN-283 | 2-naphthyl | 3-biphenyl |
| AN-284 | 2-naphthyl | 4-biphenyl |
| AN-285 | 9-phenanthryl | 1-pyrenyl |
| AN-286 | 9-phenanthryl | phenyl |
| AN-287 | 9-phenanthryl | 2-biphenyl |
| AN-288 | 9-phenanthryl | 3-biphenyl |
| AN-289 | 9-phenanthryl | 4-biphenyl |
| AN-290 | 1-pyrenyl | phenyl |
| AN-291 | 1-pyrenyl | 2-biphenyl |
| AN-292 | 1-pyrenyl | 3-biphenyl |
| AN-293 | 1-pyrenyl | 4-biphenyl |
| AN-294 | phenyl | 2-biphenyl |
| AN-295 | phenyl | 3-biphenyl |
| AN-296 | phenyl | 4-biphenyl |
| AN-297 | 2-biphenyl | 3-biphenyl |
| AN-298 | 2-biphenyl | 4-biphenyl |
| AN-299 | 3-biphenyl | 4-biphenyl |

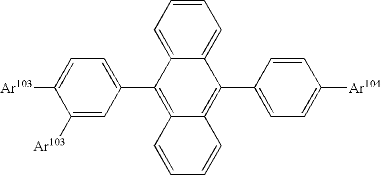

| | | |
|---|---|---|
| AN-300 | 1-naphthyl | 1-naphthyl |
| AN-301 | 1-naphthyl | 2-naphthyl |
| AN-302 | 1-naphthyl | 9-phenanthryl |
| AN-303 | 1-naphthyl | 1-pyrenyl |
| AN-304 | 1-naphthyl | phenyl |
| AN-305 | 1-naphthyl | 2-biphenyl |
| AN-306 | 1-naphthyl | 3-biphenyl |
| AN-307 | 1-naphthyl | 4-biphenyl |
| AN-308 | 1-naphthyl | 2-p-terphenyl |
| AN-309 | 2-naphthyl | 1-naphthyl |
| AN-310 | 2-naphthyl | 2-naphthyl |
| AN-311 | 2-naphthyl | 9-phenanthryl |
| AN-312 | 2-naphthyl | 1-pyrenyl |
| AN-313 | 2-naphthyl | phenyl |
| AN-314 | 2-naphthyl | 2-biphenyl |
| AN-315 | 2-naphthyl | 3-biphenyl |
| AN-316 | 2-naphthyl | 4-biphenyl |
| AN-317 | 2-naphthyl | 2-p-terphenyl |

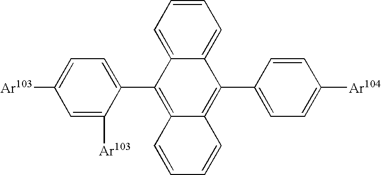

| | | |
|---|---|---|
| AN-318 | 1-naphthyl | 1-naphthyl |
| AN-319 | 1-naphthyl | 2-naphthyl |
| AN-320 | 1-naphthyl | 9-phenanthryl |
| AN-321 | 1-naphthyl | 1-pyrenyl |
| AN-322 | 1-naphthyl | phenyl |
| AN-323 | 1-naphthyl | 2-biphenyl |
| AN-324 | 1-naphthyl | 3-biphenyl |
| AN-325 | 1-naphthyl | 4-biphenyl |
| AN-326 | 1-naphthyl | 2-p-terphenyl |
| AN-327 | 2-naphthyl | 1-naphthyl |
| AN-328 | 2-naphthyl | 2-naphthyl |
| AN-329 | 2-naphthyl | 9-phenanthryl |
| AN-330 | 2-naphthyl | 1-pyrenyl |
| AN-331 | 2-naphthyl | phenyl |
| AN-332 | 2-naphthyl | 2-biphenyl |
| AN-333 | 2-naphthyl | 3-biphenyl |
| AN-334 | 2-naphthyl | 4-biphenyl |
| AN-335 | 2-naphthyl | 2-p-terphenyl |

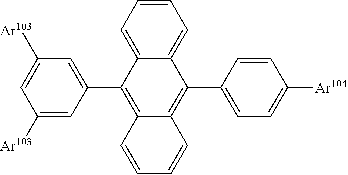

| | | |
|---|---|---|
| AN-336 | 1-naphthyl | 1-naphthyl |
| AN-337 | 1-naphthyl | 2-naphthyl |
| AN-338 | 1-naphthyl | 9-phenanthryl |
| AN-339 | 1-naphthyl | 1-pyrenyl |
| AN-340 | 1-naphthyl | phenyl |
| AN-341 | 1-naphthyl | 2-biphenyl |
| AN-342 | 1-naphthyl | 3-biphenyl |
| AN-343 | 1-naphthyl | 4-biphenyl |
| AN-344 | 1-naphthyl | 2-p-terphenyl |
| AN-345 | 2-naphthyl | 1-naphthyl |
| AN-346 | 2-naphthyl | 2-naphthyl |
| AN-347 | 2-naphthyl | 9-phenanthryl |
| AN-348 | 2-naphthyl | 1-pyrenyl |
| AN-349 | 2-naphthyl | phenyl |
| AN-350 | 2-naphthyl | 2-biphenyl |
| AN-351 | 2-naphthyl | 3-biphenyl |
| AN-352 | 2-naphthyl | 4-biphenyl |
| AN-353 | 2-naphthyl | 2-p-terphenyl |

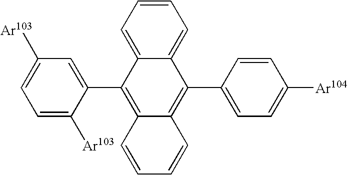

| | | |
|---|---|---|
| AN-354 | 1-naphthyl | 1-naphthyl |
| AN-355 | 1-naphthyl | 2-naphthyl |
| AN-356 | 1-naphthyl | 9-phenanthryl |
| AN-357 | 1-naphthyl | 1-pyrenyl |
| AN-358 | 1-naphthyl | phenyl |
| AN-359 | 1-naphthyl | 2-biphenyl |
| AN-360 | 1-naphthyl | 3-biphenyl |
| AN-361 | 1-naphthyl | 4-biphenyl |
| AN-362 | 1-naphthyl | 2-p-terphenyl |
| AN-363 | 2-naphthyl | 1-naphthyl |
| AN-364 | 2-naphthyl | 2-naphthyl |
| AN-365 | 2-naphthyl | 9-phenanthryl |
| AN-366 | 2-naphthyl | 1-pyrenyl |
| AN-367 | 2-naphthyl | phenyl |
| AN-368 | 2-naphthyl | 2-biphenyl |
| AN-369 | 2-naphthyl | 3-biphenyl |
| AN-370 | 2-naphthyl | 4-biphenyl |
| AN-371 | 2-naphthyl | 2-p-terphenyl |

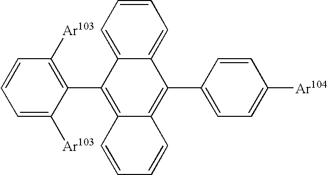

| | | |
|---|---|---|
| AN-372 | 1-naphthyl | 1-naphthyl |
| AN-373 | 1-naphthyl | 2-naphthyl |
| AN-374 | 1-naphthyl | 9-phenanthryl |
| AN-375 | 1-naphthyl | 1-pyrenyl |
| AN-376 | 1-naphthyl | phenyl |
| AN-377 | 1-naphthyl | 2-biphenyl |
| AN-378 | 1-naphthyl | 3-biphenyl |
| AN-379 | 1-naphthyl | 4-biphenyl |
| AN-380 | 1-naphthyl | 2-p-terphenyl |
| AN-381 | 2-naphthyl | 1-naphthyl |
| AN-382 | 2-naphthyl | 2-naphthyl |
| AN-383 | 2-naphthyl | 9-phenanthryl |
| AN-384 | 2-naphthyl | 1-pyrenyl |
| AN-385 | 2-naphthyl | phenyl |
| AN-386 | 2-naphthyl | 2-biphenyl |
| AN-387 | 2-naphthyl | 3-biphenyl |
| AN-388 | 2-naphthyl | 4-biphenyl |
| AN-389 | 2-naphthyl | 2-p-terphenyl |

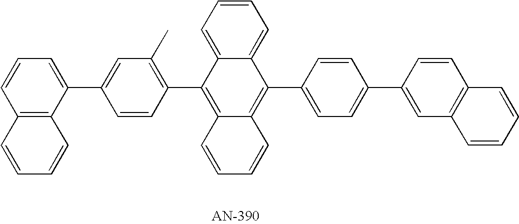

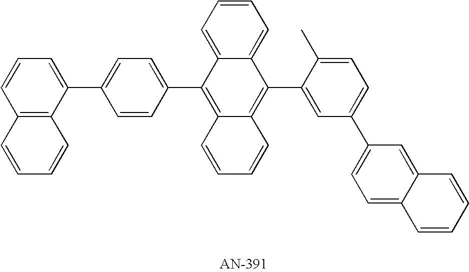

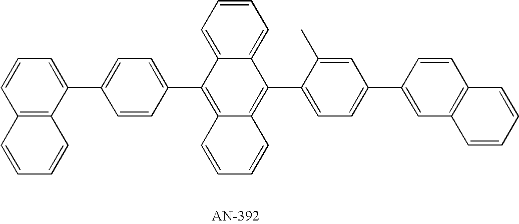

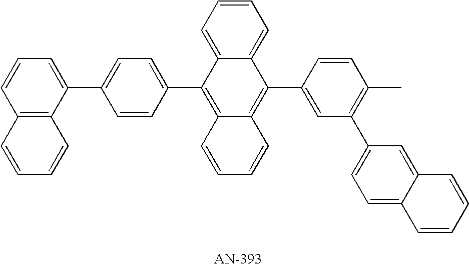

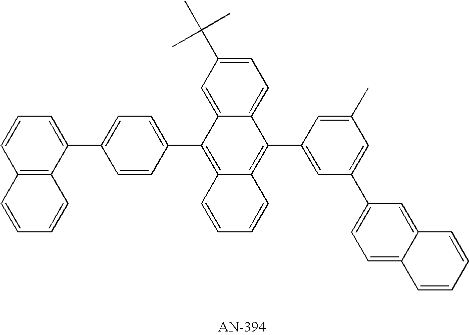

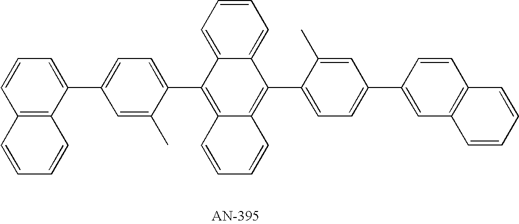

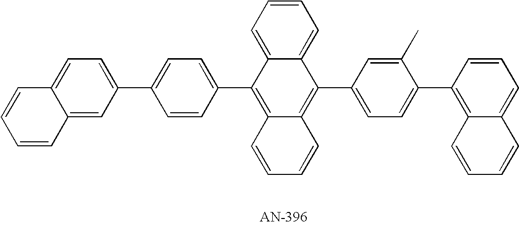

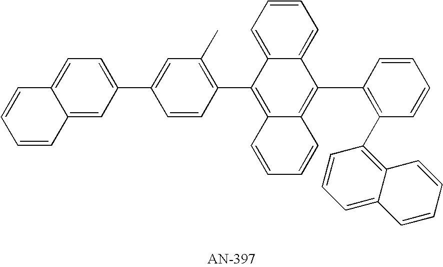

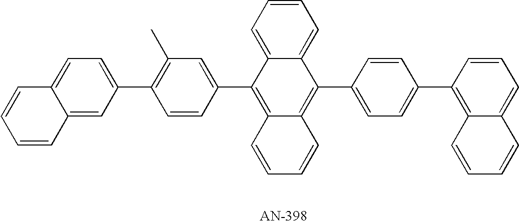

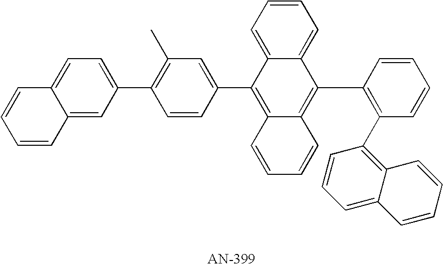

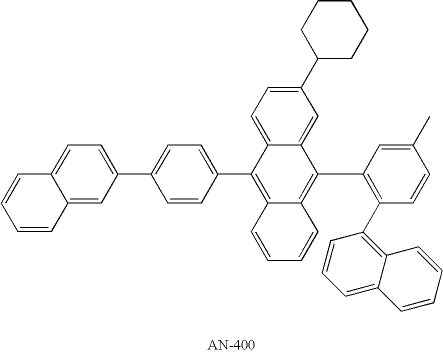

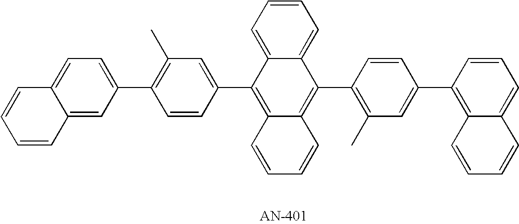

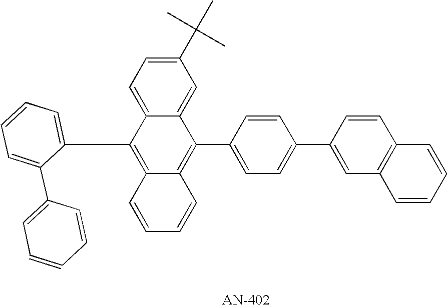

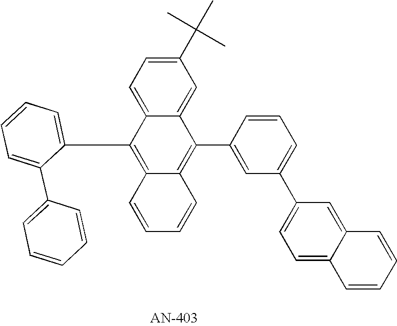

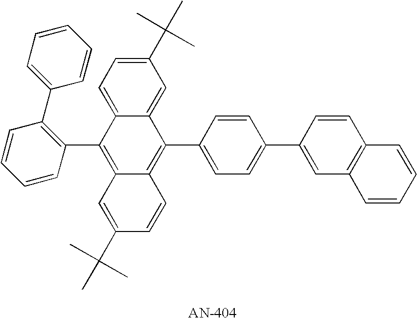

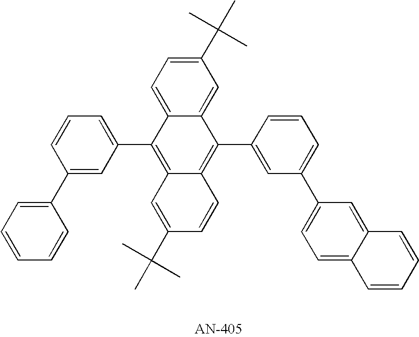

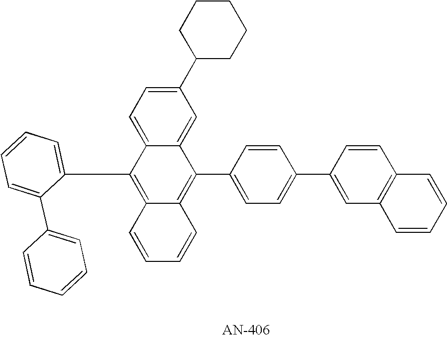

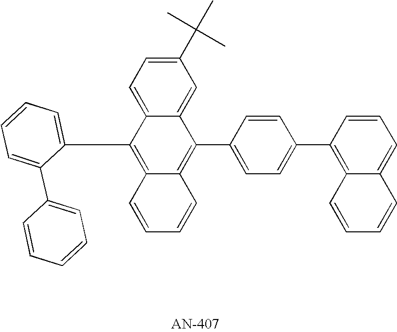

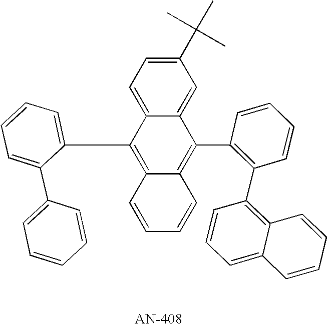

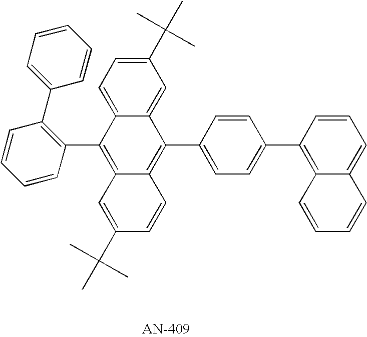

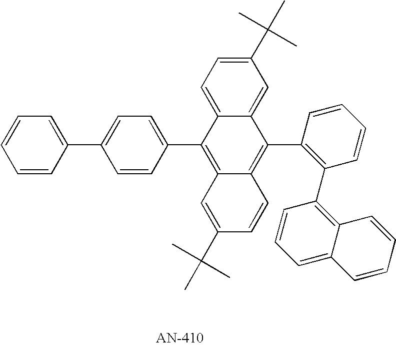

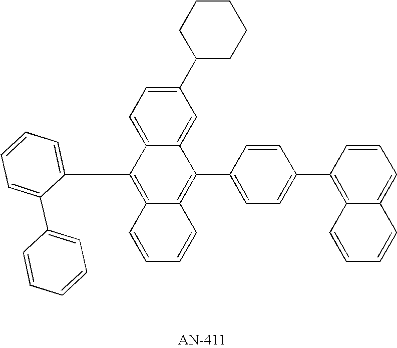

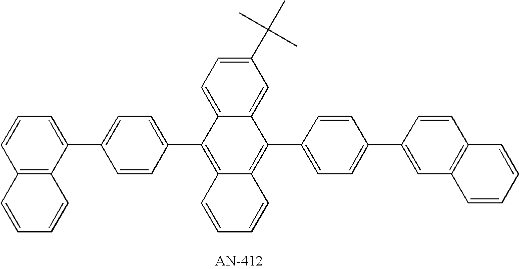

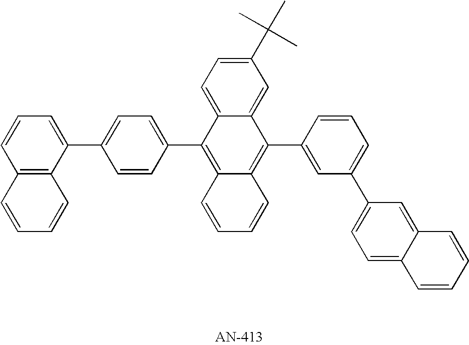

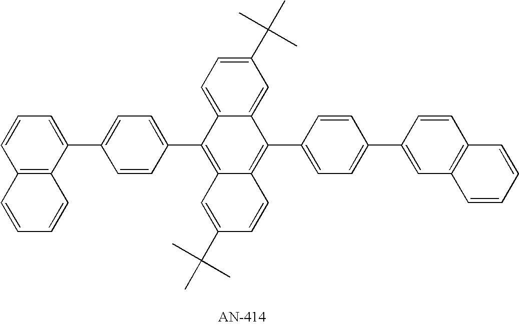

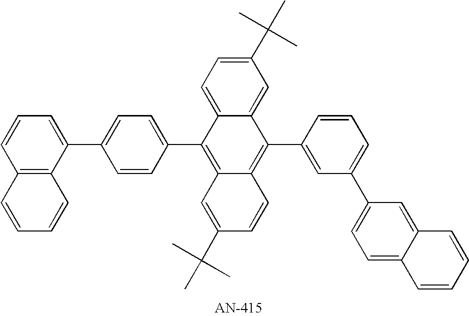

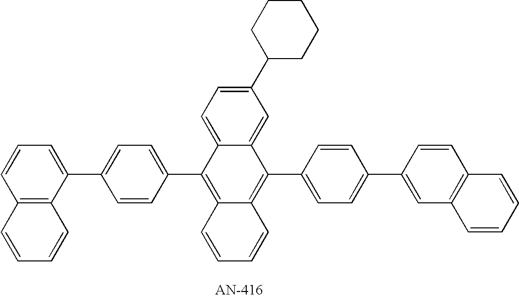

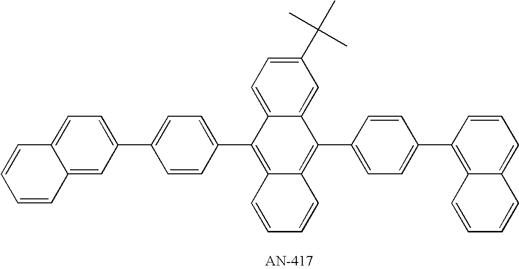

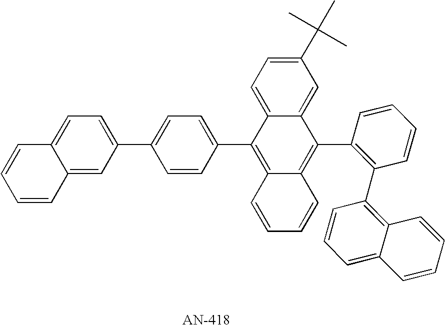

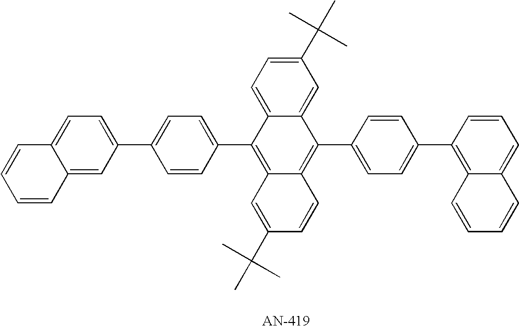

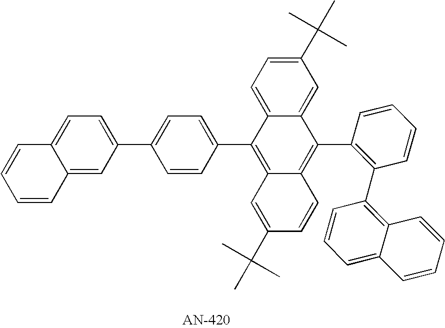

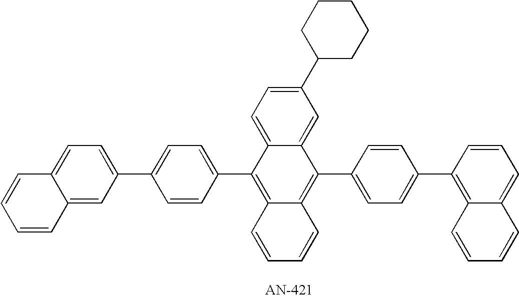

Furthermore, as an unsymmetric anthracene derivative, the compounds represented by Formula (4) below can be exemplified. 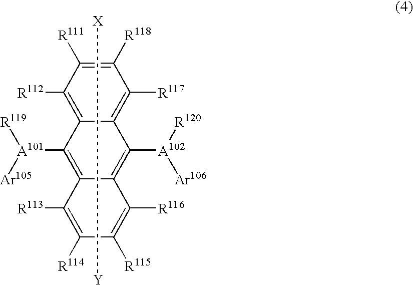
wherein Ar¹⁰¹ and Ar¹⁰² are independently a substituted or unsubstituted condensed aromatic ring group having 10 to 20 nucleus carbon atoms,

Ar¹⁰⁵ and Ar¹⁰⁶ are independently a hydrogen atom or a substituted or unsubstituted aromatic ring group having 6 to 50 nucleus carbon atoms,

R¹¹¹ to R¹²⁰ are independently a hydrogen atom or a substituted or unsubstituted aromatic ring group having 6 to 50 nucleus carbon atoms, a substituted or unsubstituted aromatic heterocyclic ring group having 5 to 50 nucleus carbon atoms, a substituted or unsubstituted alkyl group having 1 to 50 carbon atoms, a substituted or unsubstituted cycloalkyl group, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 nucleus carbon atoms, a substituted or unsubstituted arylthio group having 5 to 50 nucleus carbon atoms, a substituted or unsubstituted alkoxycarbonyl group having 1 to 50 carbon atoms, a substituted or unsubstituted silyl group, a carboxyl group, a halogen atom, a cyano group, a nitro group or a hydroxyl group, and

adjacent Ar¹⁰⁵, Ar¹⁰⁶, R¹¹⁹ and R¹²⁰ may form a saturated or unsaturated ring structure,

provided that in Formula (4), groups do not symmetrically bond to the 9 and 10 positions of the central anthracene with respect to the X-Y axis on the anthracene.

Specific compounds are shown below.

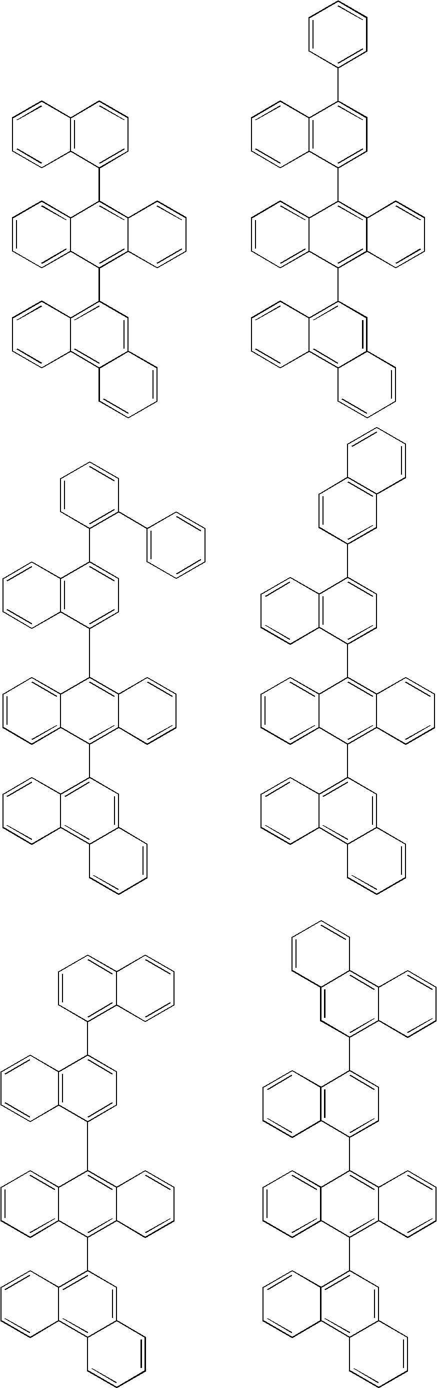

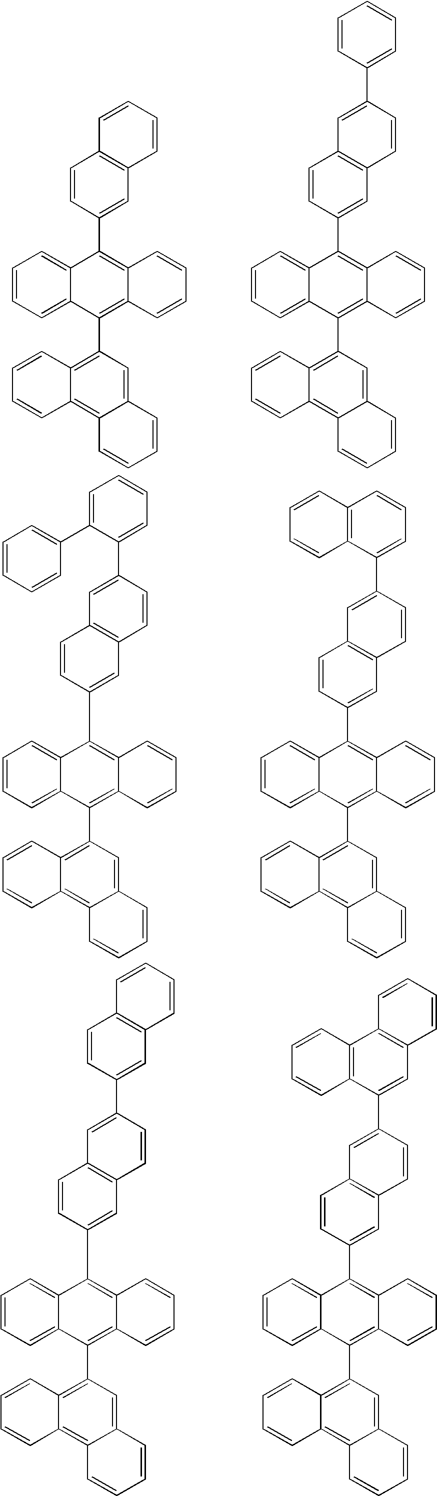

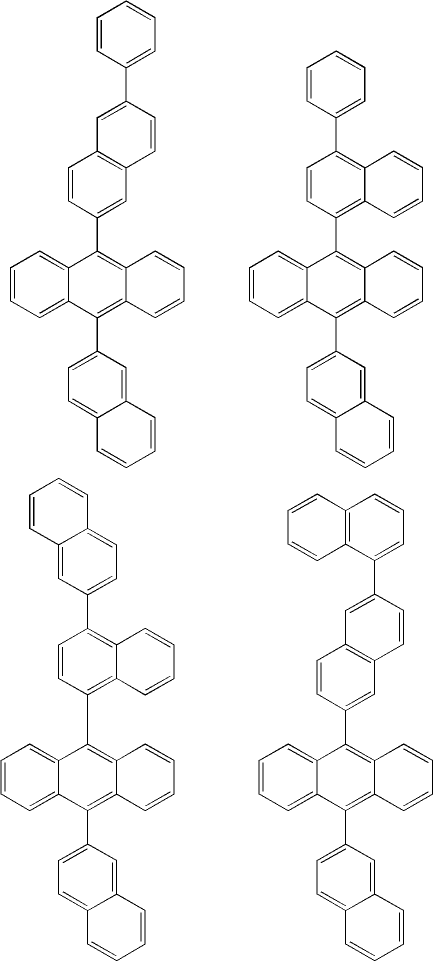

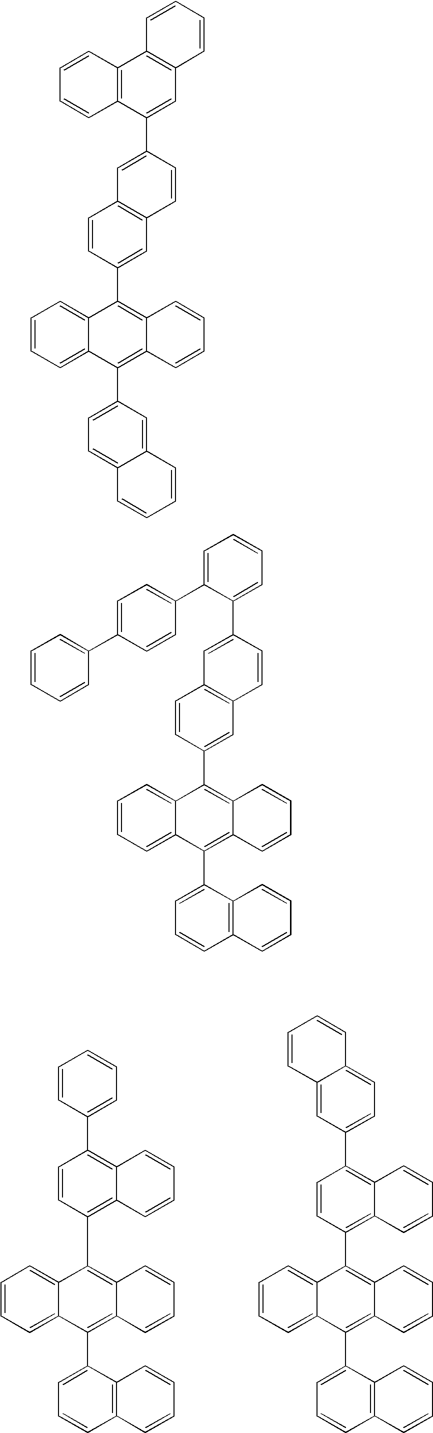

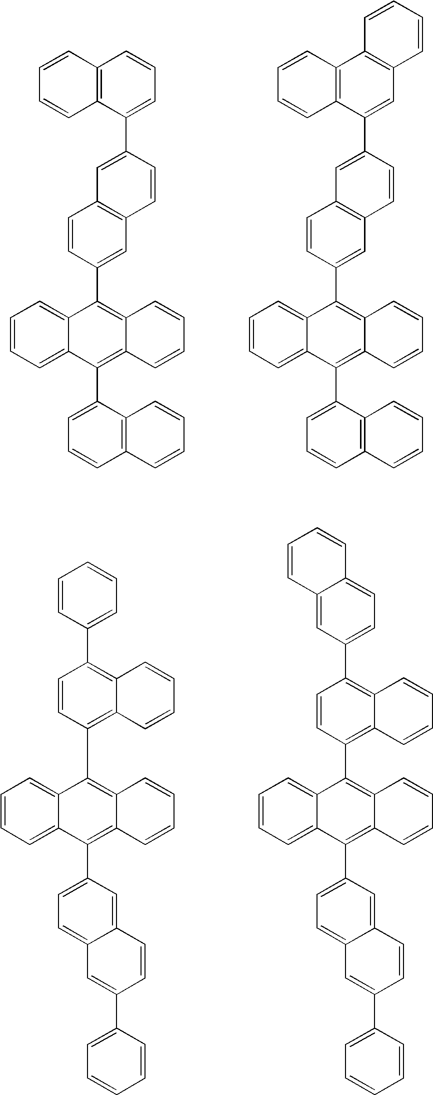

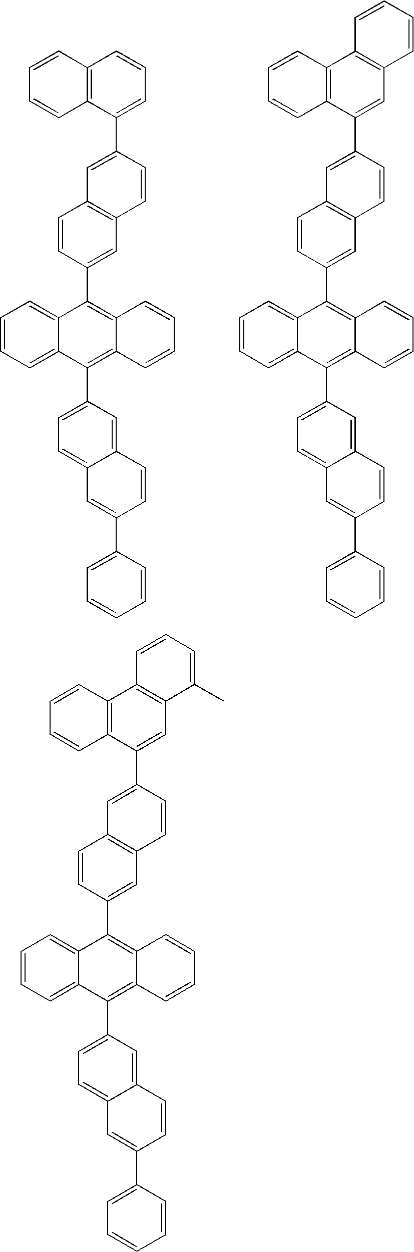

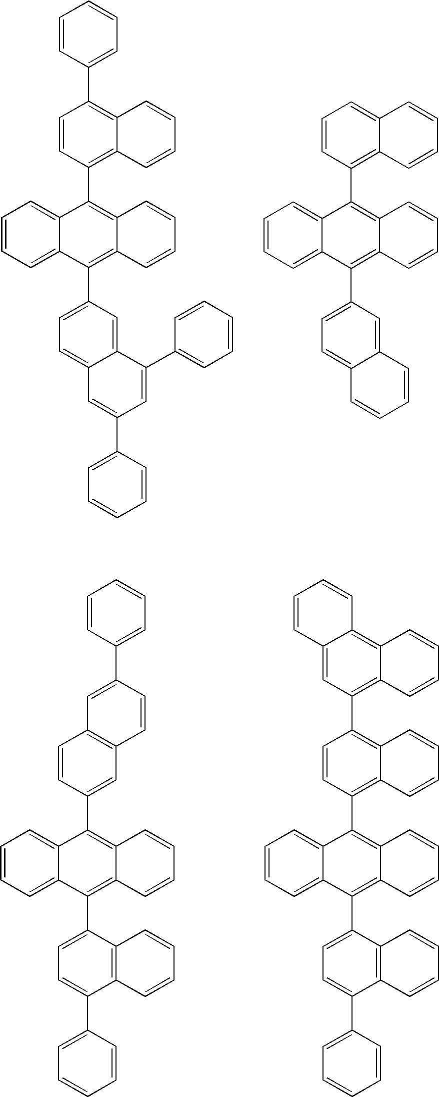

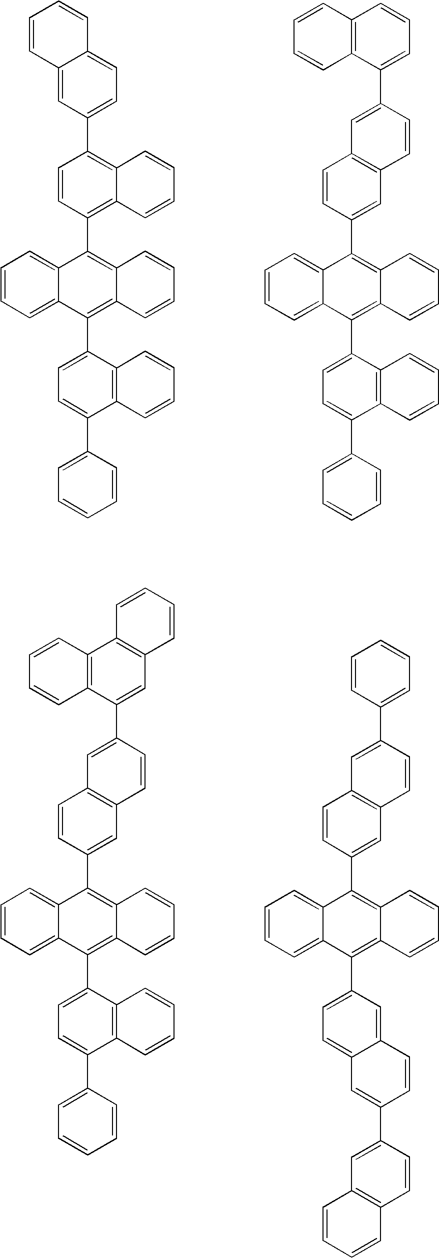

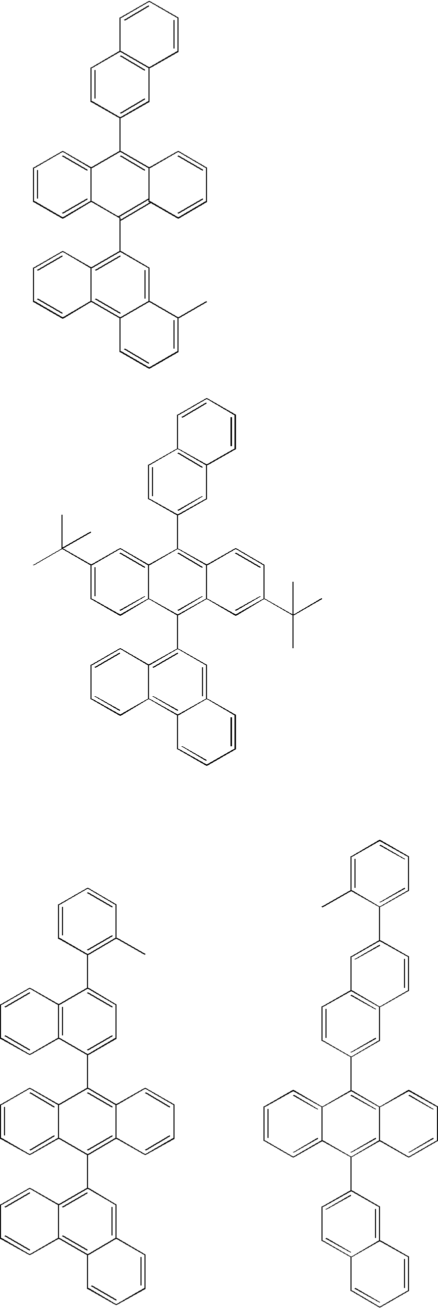

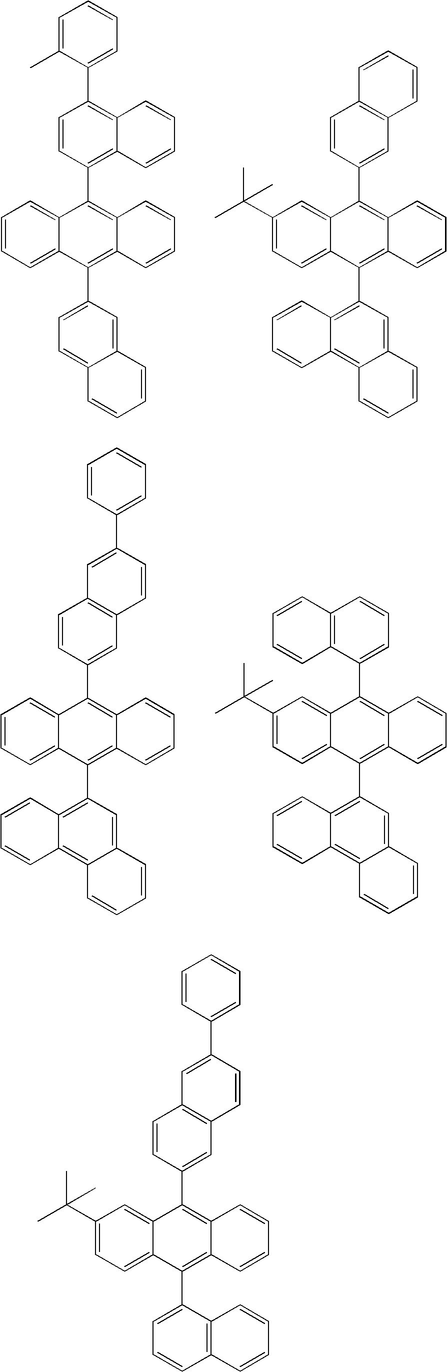

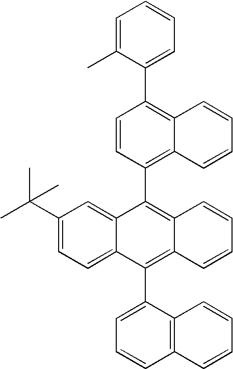

As examples of the asymmetrical pyrene derivatives, the following compound represented by Formula (5) may be illustrated: 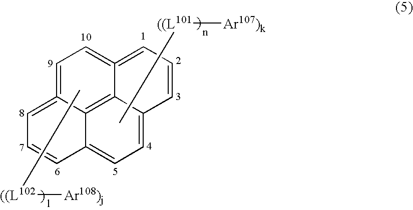
wherein Ar¹⁰⁷ and Ar¹⁰⁸ are each a substituted or unsubstituted aromatic group having 6 to 50 nucleus carbon atoms, provided that Ar¹⁰⁷ and Ar¹⁰⁸ contain no pyrene skeleton;

L¹⁰¹ and L¹⁰² are each a substituted or unsubstituted phenylene group, a substituted or unsubstituted naphthalene group, a substituted or unsubstituted fluolenylene group, or a substituted or unsubstituted dibenzosilolylene group;

n is an integer of 0 to 2, k is an integer of 1 to 4, l is an integer of 0 to 2, and j is an integer of 0 to 4;

L¹⁰¹ or Ar¹⁰⁷ bonds at any one position of 1 to 5 of the pyrene, and L¹⁰² or Ar¹⁰⁸ bonds at any one position of 6 to 10 of the pyrene;

provided that when k+j is an even number, Ar¹⁰⁷, Ar¹⁰⁸, L¹⁰¹ and L¹⁰² satisfy the following conditions (1) and (2):
(1) Ar¹⁰⁷≠Ar¹⁰⁸ and/or L¹⁰¹≠L¹⁰² where ≠ means these substituents are groups having a different structure from each other.
(2) when Ar¹⁰⁷=Ar¹⁰⁸ and L¹⁰¹=L¹⁰²,
   (2-1) n≠1 and/or k≠j, or
   (2-2) when n=1 and k=j,
      (2-2-1) L¹⁰¹ and L¹⁰², or the pyrene each bond to Ar¹⁰⁷ and Ar¹⁰⁸ at a different position, or
      (2-2-2) when L¹⁰¹ and L¹⁰², or the pyrene each bond to Ar¹⁰⁷ and Ar¹⁰⁸ at the same position, L¹⁰¹ and L¹⁰², or Ar¹⁰⁷ and Ar¹⁰⁸ are not symmetrically substituted with respect to the pyrene.

Preferably, L¹⁰¹ or L¹⁰² is phenyl.

Preferably, Ar¹⁰⁷ or Ar¹⁰⁸ is naphthyl.

n and l are preferably 1.

k is preferably 1. j is preferably 0 or 1, and more preferably 0.

Specific compounds are shown below.

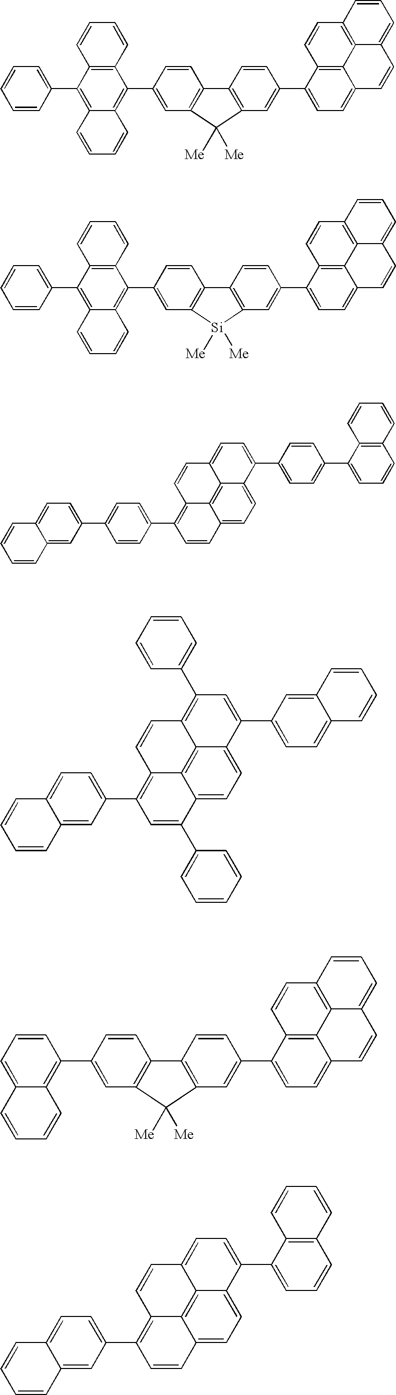

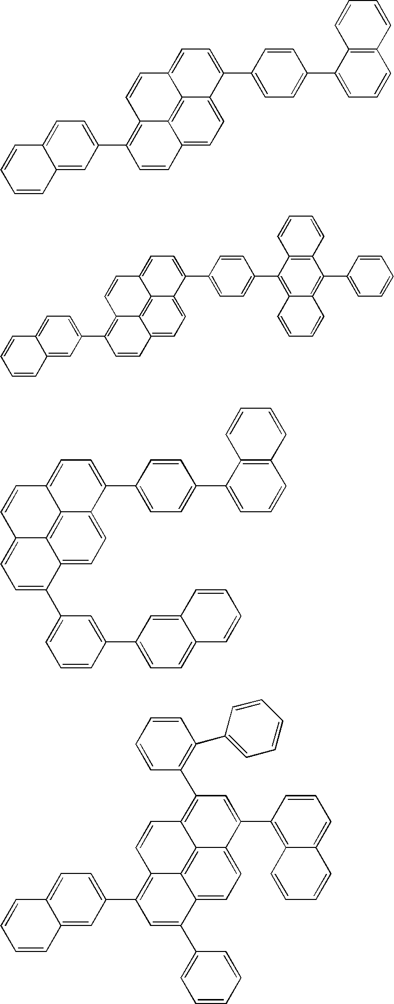

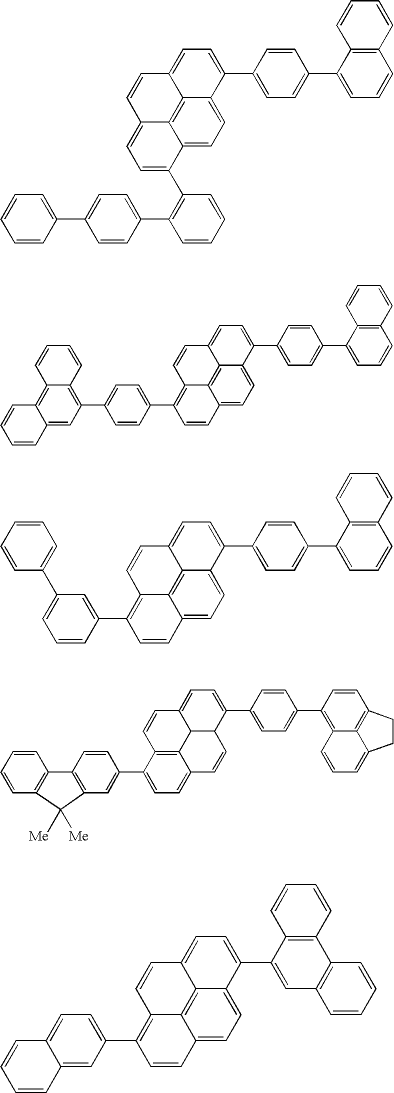

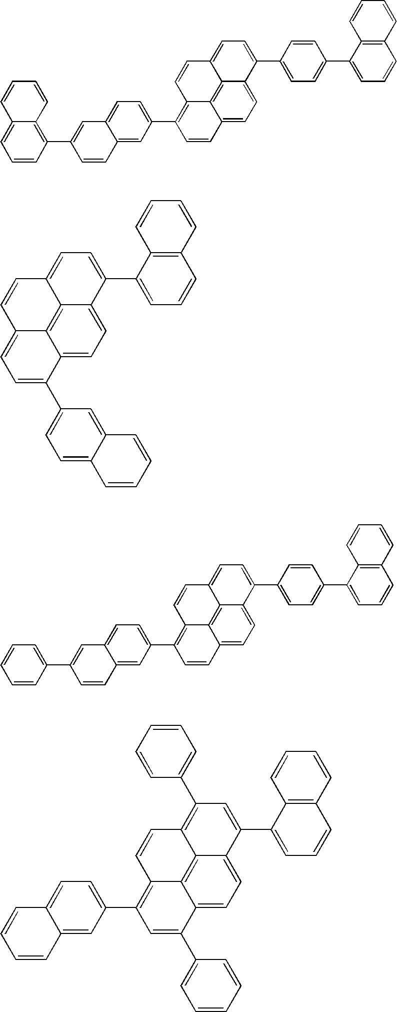

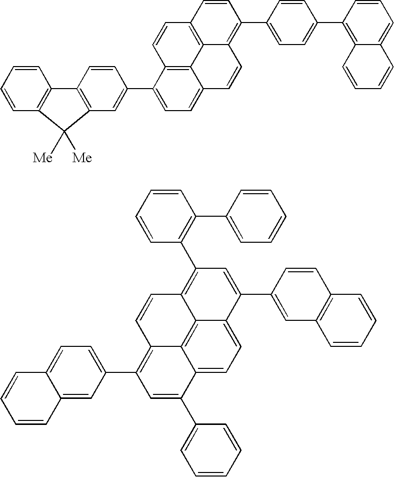

Next, the amine derivative represented by Formula (1) above will be described.

In Formula (1), Ar¹ to Ar⁴ are independently a substituted or unsubstituted aromatic ring having 6 to 50 nucleus carbon atoms. Ar¹ to Ar⁴ are preferably independently a phenyl group or a fluorenyl group which is substituted or unsubstituted with an alkyl group having 1 to 6 (preferably 1 to 4) carbon atoms, more preferably a phenyl group.

In Formula (1), R¹ and R² are the same or different substituents and may be bonded to each other to form a saturated or unsaturated ring.

Examples of R¹ and R² include a hydrogen atom, a substituted or unsubstituted alkyl group, a substituted or unsubstituted aralkyl group, a substituted or unsubstituted aryl group, a substituted or unsubstituted heterocyclic group, a substituted amino group, a cyano group or a halogen atom.

Further, examples of R¹ and R² are shown below.

Examples of the alkyl group include methyl, ethyl, n-propyl, iso-propyl, n-butyl, ter-butyl, and octyl groups.

Examples of the aralkyl group include benzyl and phenethyl groups.

Examples of the aryl group include phenyl, biphenyl and terphenyl groups.

Examples of the heterocyclic group include thienyl, pyrrolyl, pyridyl, oxazolyl, oxadiazolyl, thiazolyl, thiadiazolyl and terthienyl groups.

Examples of the substituted amino group include demethylamino, diethylamino, dibenzylamino, diphenylamino, ditolylamino and dianisolylamino groups.

Examples of the halogen atom include fluorine, chlorine, bromine and iodine.

Substituents in preferable examples of R¹ and R² include an alkyl group such as methyl, ethyl and propyl groups, an aralkyl group such as benzyl and phenethyl groups, an aryl group such as phenyl and biphenyl groups, a heterocyclic group such as thienyl, pyrrolyl and pyridyl groups, an amino group such as dimethylamino, diethylamino, dibenzylamino, diphenylamino, ditolylamino and dianisolylamino groups, an alkoxy group such as methoxyl, ethoxyl, propoxyl and phenoxyl groups, a cyano group and halogen atoms such as fluorine, chlorine, bromine and iodine.

R¹ and R² are preferably bonded to each other to form a substituted or unsubstituted saturated or unsaturated ring having 5 to 10 carbon atoms, and more preferably form a saturated ring. Saturated or unsaturated rings made of R¹ and R² bonding to different fluorene groups may be the same or different.

In Formula (1), R¹ and R² are preferably independently an alkyl group having 1 to 6 (preferably 1 to 4) carbon atoms or an aryl group having 6 to 40 carbon atoms or, preferably form to a cycloalkyl group having 4 to 7 carbon atoms, and more preferably an alkyl group having 1 to 6 (preferably 1 to 4) carbon atoms

p is an integer of 1 to 6, preferably 2 to 4, and particularly preferably 3.

Examples of the amine derivative are shown below, but it is not limited to these.

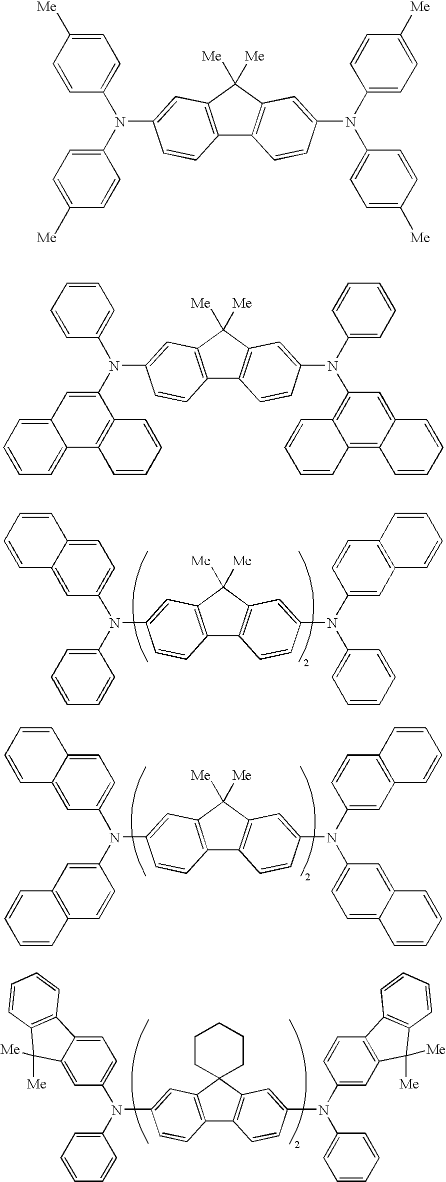

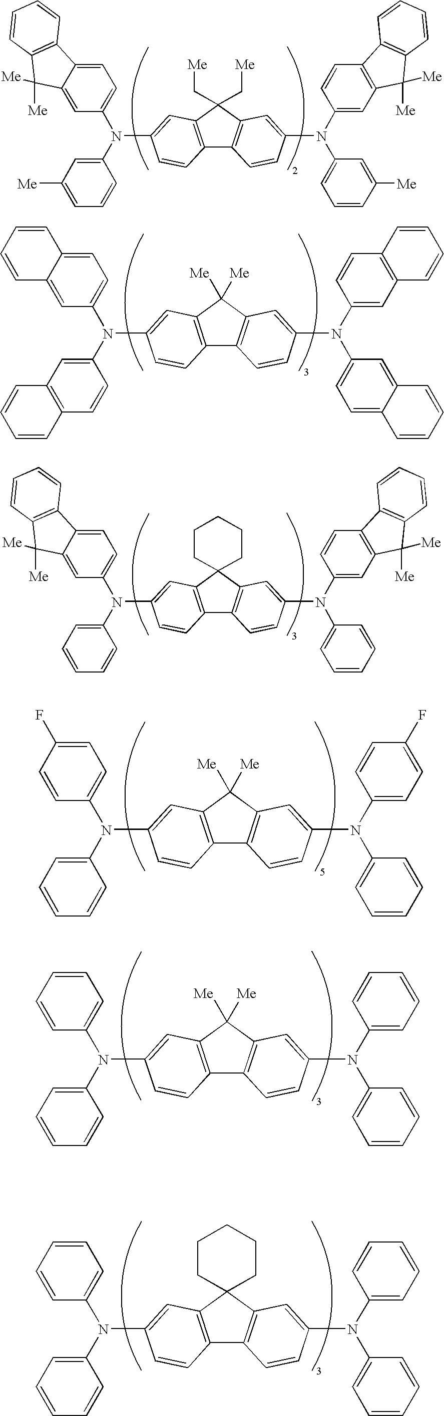

wherein Me is a methyl group.

The unsymmetric anthracene derivative or the pyrene derivative can be formed by the methods described in Japanese Patent Application No. 2002-243545, 2003-401038, 2003-423317 and so on, and the amine derivative of Formula (1) can be formed by the methods described in Japanese Patent Application No. 2004-157571 and so on.

The amine derivative of Formula (1) is preferably contained in an amount of 0.1 to 20 weight % in an emitting layer.

Next, other structures of the organic EL device of the invention are described.

(1) Structure of the Organic EL Device

The organic EL device of the invention has an emitting layer or a stacked body including an emitting layer (organic layer) held between a pair of electrodes, an anode and a cathode. The stacked body (organic layer) here includes at least one layer made of an organic material. All the layers forming the organic layer are not required to be formed from organic materials and the organic layer can include a layer formed from an inorganic material. Typical examples of structure of the organic EL device used in the invention are shown below. The invention is not limited to these. The following is exemplified.

(a) Anode/emitting layer/cathode,

(b) Anode/hole-injecting layer/emitting layer/cathode,

(c) Anode/emitting layer/electron-injecting layer/cathode,

(d) Anode/hole-injecting layer/emitting layer/electron-injecting layer/cathode,

(e) Anode/organic semiconductive layer/emitting layer/cathode,

(f) Anode/organic semiconductive layer/electron barrier layer/ emitting layer/cathode,

(g) Anode/organic semiconductive layer/emitting layer/adhesion improving layer/cathode,

(h) Anode/hole-injecting layer/hole transporting layer/emitting layer/electron-injecting layer/cathode,

(i) Anode/insulative layer/emitting layer/insulative layer/cathode,

(j) Anode/inorganic semiconductive layer/insulative layer/emitting layer/insulative layer/cathode,

(k) Anode/organic semiconductive layer/insulative layer/emitting layer/insulative layer/cathode,

(1) Anode/insulative layer/hole-injecting layer/hole transporting layer/emitting layer/insulative layer/cathode, and

(m) Anode/insulative layer/hole-injecting layer/hole transporting layer/emitting layer/electron-injecting layer/cathode.

Among these, the structure (h) is generally preferably used.

(2) Transparent Substrate

The organic EL device of the invention is fabricated on a substrate. When light is taken out through the substrate, the substrate needs to be transparent. The transparent substrate is a substrate for supporting the organic EL device, and is preferably a flat and smooth substrate having a transmittance of 50% or more to light rays within visible ranges of 400 to 700 nm.

Specific examples thereof include a glass plate and a polymer plate. Examples of the glass plate include soda-lime glass, barium/strontium-containing glass, lead glass, aluminosilicate glass, borosilicate glass, barium borosilicate glass, and quartz. Examples of the polymer plate include polycarbonate, acrylic polymer, polyethylene terephthalate, polyethersulfide, and polysulfone.

(3) Anode

The anode of the organic thin film EL device plays a role for injecting holes into its hole-transporting layer or emitting layer. The anode effectively has a work function of 4.5 eV or more. Specific examples of the material of the anode used in the invention include indium tin oxide alloy (ITO), zinc tin oxide alloy (IZO), tin oxide (NESA), gold, silver, platinum, and copper. As the cathode, materials having a small work function are preferable to inject electrons into an electron-transporting layer or an emitting layer.

The anode can be formed by making these electrode materials into a thin film by vapor deposition, sputtering or the like.

In the case where light emitted from the emitting layer is taken out through the anode, the transmittance of the anode relative to the emitted light is preferably more than 10%. The sheet resistance of the anode is preferably several hundreds Ω/□ or less. The film thickness of the anode, which may vary dependent upon the material thereof, is usually from 10 nm to 1 μm, preferably from 10 to 200 nm.

(4) Emitting Layer

An emitting layer of an organic EL device possesses the following functions:

(a) an injection function; which enables to inject holes from an anode or hole-injecting layer and to inject electrons from a cathode or electron-injecting layer, when an electric field is applied,

(b) a transport function; which transports injected electric charge (electrons and holes) with an electric field's power, and

(c) an emitting function; which provides a re-combination site for electrons and holes to emit light.

There may be a difference in ease of injection between holes and electrons, and also a difference in transport capacity that is represented by mobilities of holes and electrons. However, moving one of the electric charges is preferred.

As methods of forming this emitting layer, known methods such as vacuum deposition, spin coating and LB technique can be applied. An emitting layer is particularly preferably a molecule-deposited film.

The term “molecule-deposited film” here means a thin film that is formed by depositing a material compound in a vapor phase and a film formed by solidifying a material compound in a solution state or liquid state. Usually this molecule-deposited film can be distinguished from a thin film formed by the LB technique (a molecule-accumulated film) by differences in agglutination structure and higher dimension structure, and functional differences caused thereby.

As disclosed in JP-A-57-51781, an emitting layer can also be formed by dissolving a binder such as resins and a material compound in a solvent to make a solution and forming a thin film therefrom by spin coating and so on.

The emitting layer may be formed of a single layer or stacked layers containing different emitting materials.

The emitting layer can contain a host compound or dopant compound other than the compounds mentioned above so long as the advantages of the invention are obtained.

Phosphorescent compounds can be used as a dopant of an emitting material.

When using a phosphorescent compound, compounds containing a carbazole ring are preferred for a host material.

A phosphorescent dopant is a compound that can emit light from triplet excitons. The dopant is not limited so long as it can emit light from triplet excitons, but it is preferably a metal complex containing at least one metal selected from the group of Ir, Ru, Pd, Pt, Os and Re. A porphyrin metal complex or an ortho-metalated metal complex is preferable.

The compounds containing a carbazole ring, which are a host suitable for phosphorescence emission, is a compound which allows a phosphorescent compound to emit as a result of energy transfer from its excited state to the phosphorescent compound. A host compound is not limited so long as the compound can transfer its excited energy to a phosphorescent compound and it can be selected depending on purposes. The host compound may contain any hetrocyclic ring other than a carbazole ring.

Specific examples of the host compounds include carbazole, triazole, oxazole, oxadiazole, imidazole, polyarylalkane, pyrazoline, pyrazolone, phenylanediamine, arylamine, amino-substituted calcone, styryl anthracene, fluorenone, hydrazone, stilbene and silazane derivatives; aromatic tertiary amine, styrylamine, aromatic dimethylidene and porphyrin compounds; anthraquinodimethane, anthrone, diphenylquinone, thiopyrandioxide, carbodiimide, fluoreniridenemethane and distyrylpyrazine derivatives; heterocyclic tetracarboxylic anhydrides such as naphthaleneperylene; phthalocyanine derivatives; metal complexes of 8-quinolinol derivatives; various metal complex polysilane compounds represented by metal complexes having metalphthalocyanine, benzoxazole or benzothiaole as a ligand; electroconductive macromolecular oligomers such as poly(N-vinylcarbazole) derivatives, aniline copolymers, thiophene oligomers and polythiophene; and macromolecular compounds such as polythiophene, polyphenylene, polyphenylenevinylene and polyfluorene derivatives. Host compounds can be used individually or as a combination of two or more kinds.

Specific compounds shown below can be exemplified.

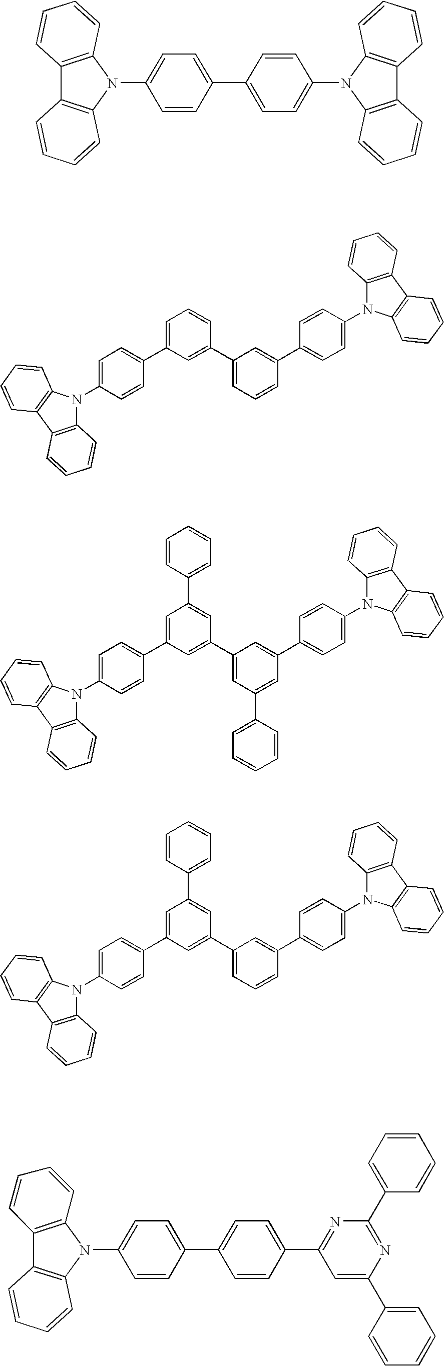

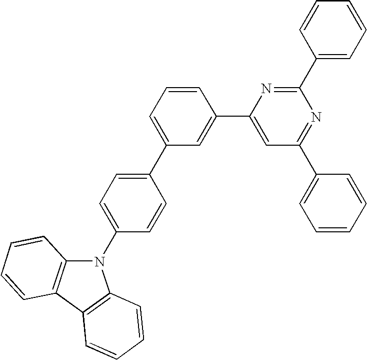

A phosphorescent dopant is a compound that can emit light from triplet excitons. The dopant is not limited so long as it can emit light from triplet excitons, but it is preferably a metal complex containing at least one metal selected from the group of Ir, Ru, Pd, Pt, Os and Re. A porphyrin metal complex or an ortho-metalated metal complex is preferable. As a porphyrin metal complex, a porphyrin platinum complex is preferable. The phosphorescent compounds can be used individually or as a combination of two or more kinds.

There are various ligands forming an ortho-metalated metal complex. Preferable ligands include 2-phenylpyridine, 7,8-benzoquinoline, 2-(2-thienyl)pyridine, 2-(1-naphtyl)pyridine and 2-phenylquinoline derivatives. These derivatives may have substituents if necessary. Fluorides and derivatives with a trifluoromethyl group introduced are particularly preferable as a blue dopant. As an auxiliary ligand, preferred are ligands other than the above-mentioned ligands, such as acetylacetonate and picric acid may be contained.

The content of a phosphorescent dopant in an emitting layer is not limited and can be properly selected according to purposes; for example, it is 0.1 to 70 mass %, preferably 1 to 30 mass %. When the content of a phosphorescent compound is less than 0.1 mass %, emission may be weak and the advantages thereof may not be sufficiently obtained. When the content exceeds 70 mass %, the phenomenon called concentration quenching may significantly proceed, thereby degrading the device performance.

The emitting layer may contain hole-transporting materials, electron-transporting materials and polymer binders if necessary.

The thickness of an emitting layer is preferably from 5 to 50 nm, more preferably from 7 to 50 nm and most preferably from 10 to 50 nm. When it is less than 5 nm, the formation of an emitting layer and the adjustment of chromaticity may become difficult. When it exceeds 50 nm, the driving voltage may increase.

(5) Hole-injecting, Transporting Layer

The hole-injecting, transporting layer is a layer for helping the injection of holes into the emitting layer so as to transport the holes to an emitting region. The hole mobility thereof is large and the ionization energy thereof is usually as small as 5.5 eV or less. Such a hole-injecting, transporting layer is preferably made of a material which can transport holes to the emitting layer at a lower electric field intensity. The hole mobility thereof is preferably at least 10⁻⁴ cm²/V·second when an electric field of, e.g., 10⁴ to 10⁶ V/cm is applied.

The material for forming the hole-injecting, transporting layer is not particularly limited so long as the material has the above-mentioned preferred natures. The material can be arbitrarily selected from materials which have been widely used as a hole transporting material in photoconductive materials and known materials used in a hole-injecting layer of organic EL devices.

Specific examples thereof include triazole derivatives (see U.S. Pat. No. 3,112,197 and others), oxadiazole derivatives (see U.S. Pat. No. 3,189,447 and others), imidazole derivatives (see JP-B-37-16096 and others), polyarylalkane derivatives (see U.S. Pat. Nos. 3,615,402, 3,820,989 and 3,542,544, JP-B-45-555 and 51-10983, JP-A-51-93224, 55-17105, 56-4148, 55-108667, 55-156953 and 56-36656, and others), pyrazoline derivatives and pyrazolone derivatives (see U.S. Pat. Nos. 3,180,729 and 4,278,746, JP-A-55-88064, 55-88065, 49-105537, 55-51086, 56-80051, 56-88141, 57-45545, 54-112637 and 55-74546, and others), phenylene diamine derivatives (see U.S. Pat. No. 3,615,404, JP-B-51-10105, 46-3712 and 47-25336, JP-A-54-53435, 54-110536 and 54-119925, and others), arylamine derivatives (see U.S. Pat. Nos. 3,567,450, 3,180,703, 3,240,597, 3,658,520, 4,232,103, 4,175,961 and 4,012,376, JP-B-49-35702 and 39-27577, JP-A-55-144250, 56-119132 and 56-22437, DE1,110,518, and others), amino-substituted chalcone derivatives (see U.S. Pat. No. 3,526,501, and others), oxazole derivatives (ones disclosed in U.S. Pat. No. 3,257,203, and others), styrylanthracene derivatives (see JP-A-56-46234, and others), fluorenone derivatives (JP-A-54-110837, and others), hydrazone derivatives (see U.S. Pat. No. 3,717,462, JP-A-54-59143, 55-52063, 55-52064, 55-46760, 55-85495, 57-11350, 57-148749 and 2-311591, and others), stilbene derivatives (see JP-A-61-210363, 61-228451, 61-14642, 61-72255, 62-47646, 62-36674, 62-10652, 62-30255, 60-93455, 60-94462, 60-174749 and 60-175052, and others), silazane derivatives (U.S. Pat. No. 4,950,950), polysilanes (JP-A-2-204996), aniline copolymers (JP-A-2-282263), and electroconductive macromolecular oligomers (in particular thiophene oligomers) disclosed in JP-A-1-211399.

As a material of the hole-injecting layer, the above-mentioned substances can be used. The following is preferably used: porphyrin compounds (disclosed in JP-A-63-2956965 and others), aromatic tertiary amine compounds and styrylamine compounds (see U.S. Pat. No. 4,127,412, JP-A-53-27033, 54-58445, 54-149634, 54-64299, 55-79450, 55-144250, 56-119132, 61-295558, 61-98353 and 63-295695, and others), in particular, the aromatic tertiary amine compounds.

The following can also be used: 4,4′-bis(N-(1-naphthyl)-N-phenylamino)biphenyl (hereinafter referred to as NPD), which has in the molecule thereof two condensed aromatic rings, disclosed in U.S. Pat. No. 5,061,569, and 4,4′,4″-tris(N-(3-methylphenyl)-N-phenylamino)triphenylamine (hereinafter referred to as MTDATA), wherein three triphenylamine units are linked to each other in a star-burst form, disclosed in JP-A-4-308688.

Inorganic compounds, such as p-type Si and p-type SiC, as well as the above-mentioned compounds listed as the material of the emitting layer can also be used as the material of the hole-injecting layer.

The hole-injecting, transporting layer can be formed by making the above-mentioned compound(s) into a thin film by a known method, such as vacuum deposition, spin coating, casting or LB technique. The film thickness of the hole-injecting, transporting layer is not particularly limited, and is usually from 5 nm to 5 μm. This hole-injecting, transporting layer may be a single layer made of one or more out of the above-mentioned materials. A hole-injecting, transporting layer made of a compound different from that in the above-mentioned hole-injecting, transporting layer may be stacked thereon.

The organic semiconductive layer is a layer for helping the injection of holes or electrons into the emitting layer, and is preferably a layer having an electroconductivity of 10⁻¹⁰ S/cm or more. The material of such an organic semiconductive layer may be an electroconductive oligomer, such as thiophene-containing oligomer or arylamine-containing oligomer disclosed in JP-A-8-193191, an electroconductive dendrimer such as arylamine-containing dendrimer.

(6) Electron-injecting Layer

The electron-injecting layer is a layer for helping the injection of electrons into the emitting layer, and have a large electron mobility. An adhesion improving layer is a layer made of a material particularly good in adhesion to the cathode among such electron-injecting layers. The material used in the electron-injecting layer is, for example, preferably a metal complex of 8-hydroxyquinoline or a derivative thereof.

Specific examples of the above-mentioned metal complex of 8-hydroxyquinoline or its derivative include metal chelate oxynoid compounds each containing a chelate of oxine (generally, 8-quinolinol or 8-hydroxyquinoline).

For example, Alq mentioned in the emitting material section can be used as the electron-injecting layer. Examples of the oxadiazole derivative include electron transferring compounds represented by the following formulas: 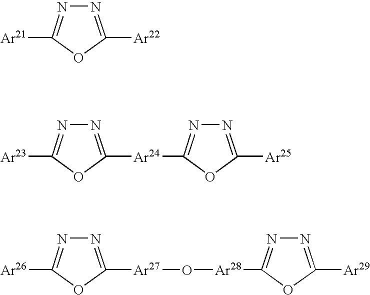
wherein Ar²¹, Ar²¹, Ar²³, Ar²⁵, Ar²⁶ and Ar²⁹ each represent a substituted or unsubstituted aryl group and may be the same or different, and Ar²⁴, Ar²⁷ and Ar²⁸ represent substituted or unsubstituted arylene groups and may be the same or different.

Examples of the aryl group include phenyl, biphenyl, anthranyl, perylenyl, and pyrenyl groups. Examples of the arylene group include phenylene, naphthylene, biphenylene, anthranylene, perylenylene, and pyrenylene groups.

Examples of the substituent include alkyl groups with 1 to carbon atoms, alkoxy groups with 1 to 10 carbon atoms, and a cyano group. The electron transferring compounds are preferably ones having capability of forming a thin film.

Specific examples of the above-mentioned electron transferring compounds include the following:

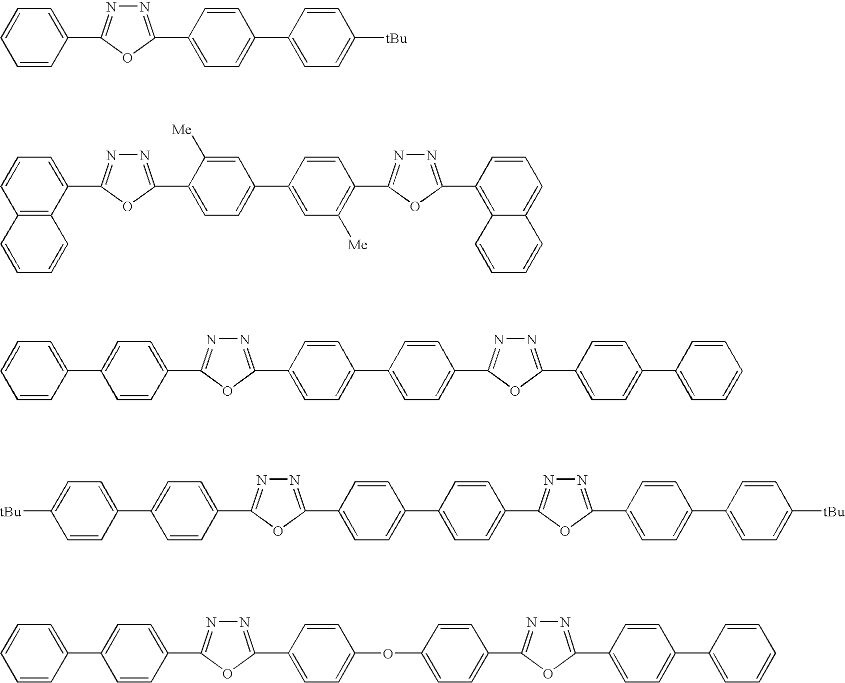

Nitrogen-containing heterocyclic compounds represented by the following formulas 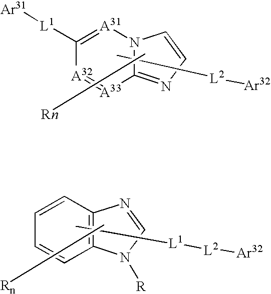
wherein A³¹ to A³³ are each a nitrogen atom or carbon atom;

R is an aryl group which has 6 to 60 carbon atoms and may have a substituent, a heteroaryl group which has 3 to 60 carbon atoms and may have a substituent, an alkyl group which has 1 to 20 carbon atoms, a haloalkyl group which has 1 to 20 carbon atoms, or an alkoxy group which has 1 to 20 carbon atoms;

n is an integer of 0 to 5 and when n is an integer of 2 or more, Rs may be the same as or different from each other.

Adjacent Rs may bond to each other to form a substituted or unsubstituted carbocyclic aliphatic ring or a substituted or unsubstituted carbocyclic aromatic ring.

Ar³¹ is an aryl group which has 6 to 60 carbon atoms and may have a substituent, or a heteroaryl group which has 3 to 60 carbon atoms and may have a substituent;

Ar³² is a hydrogen atom, an alkyl group which has 1 to 20 carbon atoms, a haloalkyl group which has 1 to 20 carbon atoms, an alkoxy group which has 1 to 20 carbon atoms, an aryl group which has 6 to 60 carbon atoms and may have a substituent, or a heteroaryl group which has 3 to 60 carbon atoms and may have a substituent;

provided that either one of Ar³¹ and Ar³² is a condensed cyclic group which has 10 to 60 carbon atoms and may have a substituent, or a condensed heterocyclic group which has 3 to 60 carbon atoms and may have a substituent;

L¹ and L² are each a single bond, a condensed cyclic group which has 6 to 60 carbon atoms and may have a substituent, a condensed heterocyclic group which has 3 to 60 carbon atoms and may have a substituent, or a fluorenylene group which may have a substituent.

Nitrogen-containing heterocyclic compounds represented by the following formula
HAr-L⁴¹-Ar⁴¹—Ar⁴²
wherein HAr is a nitrogen-containing heterocyclic ring which has 3 to 40 carbon atoms and may have a substituent;

L⁴¹ is a single bond, an arylene group which has 6 to 60 carbon atoms and may have a substituent, a heteroarylene group which has 3 to 60 carbon atoms and may have a substituent, or a fluorenylene group which may have a substituent;

Ar⁴¹ is a bivalent aromatic hydrocarbon group which has 6 to 60 carbon atoms and may have a substituent;

Ar⁴² is an aryl group which has 6 to 60 carbon atoms and may have a substituent, or a heteroaryl group which has 3 to 60 carbon atoms and may have a substituent.

A silacyclopentadiene derivative represented by the following formula 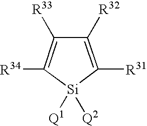
wherein Q¹ and Q² are each a saturated or unsaturated hydrocarbon group with 1 to 6 carbon atoms, an alkoxy group, an alkenyloxy group, an alkynyloxy group, a hydroxyl group, a substituted or unsubstituted aryl group, or a substituted or unsubstituted heterocyclic group, or Q¹ and Q² are bonded to each other to form a saturated or unsaturated ring; R³¹ to R³⁴ are each a hydrogen atom, a halogen atom, a substituted or unsubstituted alkyl group with 1 to 6 carbon atoms, an alkoxy group, an aryloxy group, a perfluoroalkyl group, a perfluoroalkoxy group, an amino group, an alkylcarbonyl group, an arylcarbonyl group, an alkoxycarbonyl group, an aryloxycarbonyl group, an azo group, an alkylcarbonyloxy group, an arylcarbonyloxy group, an alkoxycarbonyloxy group, an aryloxycarbonyloxy group, a sulfinyl group, a sulfonyl group, a sulfanyl group, a silyl group, a carbamoil group, an aryl group, a heterocyclic group, an alkenyl group, an alkynyl group, a nitro group, a formyl group, a nitroso group, a formyloxy group, an isocyano group, a cyanate group, an isocyanate group, a thiocyanate group, an isothiocyanate group, a cyano group, or a substituted or unsubstituted condensed ring structure formed by adjacent groups of R³¹ to R³⁴.

Silacyclopentadiene derivatives represented by the following formula 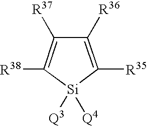
wherein Q³ and Q⁴ are each a saturated or unsaturated hydrocarbon group with 1 to 6 carbon atoms, an alkoxy group, an alkenyloxy group, an alkynyloxy group, a substituted or unsubstituted aryl group, or a substituted or unsubstituted hetero ring, or Q³ and Q⁴ are bonded to each other to form a saturated or unsaturated ring; R³⁵ to R³⁸ are each a hydrogen atom, a halogen atom, a substituted or unsubstituted alkyl group with 1 to 6 carbon atoms, an alkoxy group, an aryloxy group, a perfluoroalkyl group, a perfluoroalkoxy group, an amino group, an alkylcarbonyl group, an arylcarbonyl group, an alkoxycarbonyl group, an aryloxycarbonyl group, an azo group, an alkylcarbonyloxy group, an arylcarbonyloxy group, an alkoxycarbonyloxy group, an aryloxycarbonyloxy group, a sulfinyl group, a sulfonyl group, a sulfanyl group, a silyl group, a carbamoil group, an aryl group, a heterocyclic group, an alkenyl group, an alkynyl group, a nitro group, a formyl group, a nitroso group, a formyloxy group, an isocyano group, a cyanate group, an isocyanate group, a thiocyanate group, an isothiocyanate group or a cyano group, or adjacent groups of R³⁵ to R³⁸ may be bonded to each other to form a substituted or unsubstituted condensed ring (provided that in the case where R³⁵ and R³⁸ are a phenyl group, Q³ and Q⁴ are neither an alkyl group nor a phenyl group; in the case where R³⁵ and R³⁸ are a thienyl group, Q³, Q⁴, R³⁶ and R³⁷ do not form the structure where Q³ and Q⁴ are a monovalent hydrocarbon group, and at the same time R³⁶ and R³⁷ are an alkyl group, an aryl group, an alkenyl group, or an aliphatic group with a cycle formed by R³⁶ and R³⁷ bonded; in the case where R³⁵ and R³⁸ are a silyl group, R³⁶, R³⁷, Q³ and Q⁴ are each neither a monovalent hydrocarbon group with 1 to 6 carbon atoms nor a hydrogen atom; and in the case where R³⁵ and R³⁶ are bonded to each other to form a condensed structure with a benzene ring, Q³ and Q⁴ are neither an alkyl group nor a phenyl group).

Borane derivatives represented by Formula (1): 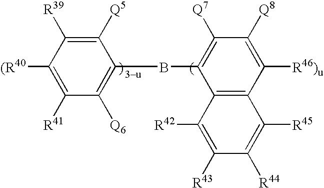
wherein R³⁹ to R⁴⁶ and Q⁸ are each a hydrogen atom, a saturated or unsaturated hydrocarbon group, an aromatic group, a heterocyclic group, a substituted amino group, a substituted boryl group, an alkoxy group or an aryloxy group; Q⁵, Q⁶ and Q⁷ are each a saturated or unsaturated hydrocarbon group, an aromatic group, a heterocyclic group, a substituted amino group, an alkoxy group or an aryloxy group; the substituent of Q⁷ and Q⁸ may be bonded to each other to form condensed rings; u is an integer of 1.to 3, and Q⁷s may be different from each other when u is 2 or more; provided that excluded are the compounds where U is 1, Q⁵, Q⁶ and R⁴⁰ are each a methyl group and R⁴⁶ is a hydrogen atom or substituted boryl group, and the compounds where u is 3 and Q⁷ is a methyl group.

Compounds represented by the following formula: 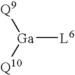
wherein Q⁹ and Q¹⁰ are independently a ligand represented by the following formula; and L is a halogen atom, a substituted or unsubstituted alkyl group, a substituted or unsubstituted cycloalkyl group, a substituted or unsubstituted aryl group, a substituted or unsubstituted heterocyclic group, —OR⁴⁷ (wherein R⁴⁷ is a hydrogen atom, a substituted or unsubstituted alkyl group, a substituted or unsubstituted cycloalkyl group, a substituted or unsubstituted aryl group, or a substituted or unsubstituted heterocyclic group), or —O—Ga-Q¹¹ (Q¹²) wherein Q¹¹ and Q¹² are the same meanings as Q⁹ and Q¹⁰. 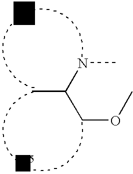
wherein rings A⁴and A⁵ are 6-membered aryl rings which may have a substituent and are condensed to each other.

The metal complexes have the strong nature of an n-type semiconductor and large ability of injecting electrons. Further, the energy generated at the time of forming a complex is small and a metal is then strongly bonded to ligands in the complex formed, and the fluorescent quantum efficiency as the emitting material is large.

Specific examples of substituents of the rings A⁴ and A⁵ which form the ligands in the above formula include halogen atoms such as chlorine, bromine, iodine and fluorine; substituted or unsubstituted alkyl groups such as methyl, ethyl, propyl, butyl, sec-butyl, tert-butyl, pentyl, hexyl, heptyl, octyl, stearyl and trichloromethyl; substituted or unsubstituted aryl groups such as phenyl, naphthyl, 3-methylphenyl, 3-methoxyphenyl, 3-fluorophenyl, 3-trichloromethylphenyl, 3-trifluoromethylphenyl and 3-nitrophenyl; substituted or unsubstituted alkoxy groups such as methoxy, n-butoxy, tert-butoxy, trichloromethoxy, trifluoroethoxy, pentafluoropropoxy, 2,2,3,3-tetrafluoropropoxy, 1,1,1,3,3,3-hexafluoro-2-propoxy and 6-(perfluoroethyl)hexyloxy; substituted or unsubstituted aryloxy groups such as phenoxy, p-nitrophenoxy, p-tert-butylphenoxy, 3-fluorophenoxy, pentafluorophenyl and 3-trifluoromethylphenoxy; substituted or unsubstituted alkylthio groups such as methythio, ethylthio, tert-butylthio, hexylthio, octylthio and trifruoromethyltio; substituted or unsubstituted arylthio groups such as phenylthio, p-nitrophenylthio, p-tert-butylphenylthio, 3-fluorophenylthio, pentafluorophenylthio and 3-trifluoromethylphenylthio; a cyano group; a nitro group, an amino group; mono or di-substituted amino groups such as methylamino, diethylamino, ethylamino, diethylamino, dipropylamino, dibutylamino and diphenylamino; acylamino groups such as bis(acetoxymethyl)amino, bis(acetoxyethyl)amino, bis(acetoxypropyl)amino and bis(acetoxybutyl)amino; a hydroxy group; a siloxy group; an acyl group; carbamoyl groups such as methylcarbamoyl, dimethylcarbamoyl, ethylcarbamoyl, diethylcarbamoyl, propylcarbamoyl, butylcarbamoyl and phenylcarbamoyl; a carboxylic group; a sulfonic acid group; an imido group; cycloalkyl groups such as cyclopentyl and cyclohexyl; aryl groups such as phenyl, naphthyl, biphenyl, anthranyl, phenanthryl, fluorenyl and pyrenyl; and heterocyclic groups such as pyridinyl, pyrazinyl, pyrimidinyl, pryidazinyl, triazinyl, indolinyl, quinolinyl, acridinyl, pyrrolidinyl, dioxanyl, piperidinyl, morpholidinyl, piperazinyl, triathinyl, carbazolyl, furanyl, thiophenyl, oxazolyl, oxadiazolyl, benzooxazolyl, thiazolyl, thiadiazolyl, benzothiazolyl, triazolyl, imidazolyl, benzoimidazolyl and puranyl. Moreover the above-mentioned substitutes may be bonded to each other to form a 6-membered aryl or heterocyclic ring.

A preferred mode of the invention is a device where a reducing dopant is contained in its electron transferring region or an interfacial region between its cathode and organic layer. The reducing dopant is defined as a substance which can reduce an electron transporting compound. Accordingly, various substances which have given reducing properties can be used. For example, at least one substance can be preferably used which is selected from the group consisting of alkali metals, alkaline earth metals, rare earth metals, alkali metal oxides, alkali metal halides, alkaline earth metal oxides, alkaline earth metal halides, rare earth metal oxides, rare earth metal halides, alkali metal organic complexes, alkaline earth metal organic complexes, and rare earth metal organic complexes.

Specifically, preferred examples of the reducing dopant include at least one alkali metal selected from the group consisting of Na (work function: 2.36 eV), K (work function: 2.28 eV), Rb (work function: 2.16 eV) and Cs (work function: 1.95 eV), and at least one alkaline earth metal selected from the group consisting of Ca (work function: 2.9 eV), Sr (work function: 2.0 to 2.5 eV), and Ba (work function: 2.52 eV). Metals having a work function of 2.9 eV or less are in particular preferred. Among these, a more preferable reducing dopant is at least one alkali metal selected from the group consisting of K, Rb and Cs. Even more preferable is Rb or Cs. Most preferable is Cs. These alkali metals are particularly high in reducing ability. Thus, the addition of a relatively small amount thereof to an electron-injecting zone makes it possible to improve the luminance of the organic EL device and make the life time thereof long. As the reducing dopant having a work function of 2.9 eV or less, any combination of two or more out of these alkali metals is also preferred. Particularly preferred is any combination containing Cs, for example, a combination of Cs and Na, Cs and K, Cs and Rb, or Cs, Na and K. The combination containing Cs makes it possible to exhibit the reducing ability efficiently. The luminance of the organic EL device can be improved and the life time thereof can be made long.

In the invention, an electron-injecting layer which is formed of an insulator or a semiconductor may further be provided between a cathode and an organic layer. Current leakage can be effectively prevented to improve the injection of electrons. As the insulator, at least one metal compound selected from alkali metal calcogenides, alkaline earth metal calcogenides, halides of alkali metals and halides of alkaline earth metals can be preferably used. If an electron-injecting layer is formed of these alkali metal calcogenide or the like, the injection of electrons can be preferably improved. Specifically preferable alkali metal calcogenides include Li₂O, LiO, Na₂S, Na₂Se and NaO and preferable alkaline earth metal calcogenides include CaO, BaO, SrO, BeO, BaS and CaSe. Preferable halides of alkali metals include LiF, NaF, KF, LiCl, KCl and NaCl. Preferable halides of alkaline earth metals include fluorides such as CaF₂, BaF₂, SrF₂, MgF₂ and BeF₂ and halides other than fluorides.

Examples of the semiconductor for forming the electron-transporting layer include oxides, nitrides or oxynitrides containing at least one element selected from Ba, Ca, Sr, Yb, Al, Ga, In, Li, Na, Cd, Mg, Si, Ta, Sb and Zn, and combinations of two or more thereof. The inorganic compound for forming the electron-transporting layer is preferably a microcrystalline or amorphous insulating thin film. If an electron-transporting layer is formed of the insulating thin film, a more uniform thin film can be formed to reduce pixel defects such as dark spots. Examples of such an inorganic compound include the above-mentioned alkali metal calcogenides, alkaline earth metal calcogenides, halides of alkali metals, and halides of alkaline earth metals.

(7) Cathode

For the cathode, the following may be used: an electrode substance made of a metal, an alloy or an electroconductive compound which has a small work function (4 eV or less), or a mixture thereof. Specific examples of the electrode substance include sodium, sodium-potassium alloy, magnesium, lithium, magnesium/silver alloy, aluminum/aluminum oxide, aluminum/lithium alloy, indium, and rare earth metals.

This cathode can be formed by making the electrode substance(s) into a thin film by vapor deposition, sputtering or some other methods.

In the invention, in the case where light emitted from the emitting layer is taken out through the cathode, it is preferred to make the transmittance of the cathode to be larger than 10%.

The sheet resistance of the cathode is preferably several hundreds Ω/□ or less, and the film thickness thereof is usually from 10 nm to 1 μm, preferably from 50 to 200 nm.

(8) Insulative Layer

In the organic EL device, pixel defects due to leakage or a short circuit are easily generated since an electric field is applied to the super thin film. In order to prevent this, it is preferred to insert an insulative thin layer between the pair of electrodes.

Examples of the material used in the insulative layer include aluminum oxide, lithium fluoride, lithium oxide, cesium fluoride, cesium oxide, magnesium oxide, magnesium fluoride, calcium oxide, calcium fluoride, aluminum nitride, titanium oxide, silicon oxide, germanium oxide, silicon nitride, boron nitride, molybdenum oxide, ruthenium oxide, and vanadium oxide.

A mixture or stacked body thereof may be used.

(9) Examples of Fabrication of Producing an Organic EL Device

The organic EL device can be fabricated by forming an anode and an emitting layer, optionally forming a hole-injecting layer and an electron-injecting layer, and further forming a cathode by use of the materials and methods exemplified above. The organic EL device can be fabricated in the order reverse to the above, i.e., the order from a cathode to an anode.

An example of the fabrication of an organic EL device will be described below which has a structure wherein the following are successively formed on a transparent substrate: anode/hole-injecting layer/emitting layer/electron-injecting layer/cathode.

First, an anode material is formed into a thin film having a thickness of 1 μm or less, preferably 10 to 200 nm on an appropriate transparent substrate by vapor deposition, sputtering or some other method, thereby forming an anode. Next, a hole-injecting layer is formed on this anode. As described above, the hole-injecting layer can be formed by vacuum deposition, spin coating, casting, LB technique, or some other methods. Vacuum deposition is preferred since a uniform film is easily obtained and pinholes are hardly generated. In the case where the hole-injecting layer is formed by vacuum deposition, conditions for the deposition are varied dependent upon the compound used (the material for the hole-injecting layer), the crystal structure or recombining structure of the desired hole-injecting layer, and others. In general, the conditions are appropriately selected from the following ranges: deposition source temperatures of 50 to 450° C., vacuum degrees of 10⁻⁷ to 10⁻³ torr, vapor deposition rates of 0.01 to 50 nm/second, substrate temperatures of −50 to 300° C., and film thicknesses of 5 nm to 5 μm.

Next, an emitting layer is disposed on the hole-injecting layer. The emitting layer can also be formed by using a desired organic emitting material and making the material into a thin film by vacuum deposition, sputtering, spin coating, casting or some other method. Vacuum deposition is preferred since a uniform film is easily obtained and pinholes are hardly generated. In the case where the emitting layer is formed by vacuum deposition, conditions for the deposition, which are varied dependent on the compound used, can be generally selected from conditions similar to those for the hole-injecting layer.

Next, an electron-injecting layer is formed on this emitting layer. Like the hole-injecting layer and the emitting layer, the layer is preferably formed by vacuum deposition in order to obtain a uniform film. Conditions for the deposition can be selected from conditions similar to those for the hole-injecting layer and the emitting layer.

When using a spin coating method, other materials can be contained in the electron-injecting layer by mixing.

Lastly, a cathode is stacked thereon to obtain an organic EL device.

The cathode is made of a metal, and vapor deposition or sputtering may be used. However, vacuum deposition is preferred in order to protect underlying organic layers from being damaged when the cathode film is formed.

It is preferred that the organic EL device fabrication from the anode to the cathode described so far is continuously carried out, using only one vacuuming operation.

The method for forming each of the layers in the organic EL device of the invention is not particularly limited. A known forming method, such as vacuum deposition or spin coating can be used. The organic thin film layers in the organic EL device of the invention can be formed by vacuum deposition, molecular beam deposition (MBE method), or a known method of applying a solution wherein organic compounds are dissolved in a solvent, such as dipping, spin coating, casting, bar coating or roll coating.

The film thickness of each of the organic layers in the organic EL device of the invention is not particularly limited. In general, defects such as pinholes are easily generated when the film thickness is too small. Conversely, a high applied voltage becomes necessary to make the efficiency bad when the film thickness is too large. Usually, therefore, the film thickness is preferably in the range of several nanometers to one micrometer.

In the case where a DC voltage is applied to the organic EL device, emission can be observed when the polarity of the anode and that of the cathode are made positive and negative, respectively, and the voltage of 5 to 40 V is applied. Even if a voltage is applied thereto in the state that the polarities are reverse to the above, no electric current flows so that emission is not generated at all. In the case where an AC voltage is applied thereto, uniform emission can be observed only when the polarity of the anode and that of the cathode are made positive and negative, respectively. The waveform of the AC to be applied may be arbitrarily selected.

### EXAMPLES

### Example 1

(1) Fabrication of Organic EL Device

A 120 nm thick transparent electrode made of indium tin oxide was formed on a glass substrate measuring 25×75×1.1 mm. The glass substrate was subjected to ultrasonic cleaning in isopropyl alcohol and cleaned by irradiating UV rays and ozone.

Next, the transparent glass substrate with the transparent electrode was set up on a substrate holder in a deposition chamber of a vacuum deposition device. After the degree of vacuum in the vacuum chamber was reduced to 1×10⁻³ Pa, a hole-injecting layer, a hole-transporting layer, an emitting layer, an electron-transporting layer, an electron-injecting layer and a cathode layer were stacked in sequence on an anode layer under the following conditions to fabricate an organic EL device.

Hole-injecting layer: N′,N″-bis[4-(diphenylamino)phenyl]-N′,N″-diphenylbiphenyl-4,4′-diamine (TPD232)

Deposition conditions; 2 nm/sec, thickness 60 nm

Hole transporting layer: N,N-bis[4′-{N-(naphthyl-1-yl)-N-phenyl}aminobiphenyl-4-yl]-N-phenylamine (TBDB)

Deposition conditions; 2 nm/sec, thickness 20 nm

Emitting layer: co-deposition of a host (ANI) and a dopant (AFII)

Deposition conditions of the host (ANI); 4 nm/sec

Deposition conditions of the dopant (AFII); 0.2 nm/sec thickness 40 nm ((ANI):(AFII)=40:2)

Electron-transporting layer: tris(8-hydroxyquinolino)aluminum (Alq)

Deposition conditions; 2 nm/sec, thickness 20 nm Electron-injecting layer: lithium fluoride

Deposition conditions; 0.1 nm/sec, thickness 1 nm

Cathode layer: aluminum

Deposition conditions; 2 nm/sec, thickness 200 nm

(2) Evaluation of Organic EL Device

Next, for the device obtained, an electrical conduction test was performed at 10 mA/cm² and the voltage was measured. The emission color was blue. Further, the period of time (lifetime) until the luminance was reduced by 10% was measured under a DC driving at room temperature at an initial luminance of 5000 nit. The results obtained were shown in Table 1.

### Examples 2 to 4

In Examples 2 to 4, organic EL devices were fabricated in the same manner as in Example 1 except that the following hosts and dopants were used for an emitting layer instead of the host (ANI) and the dopant (AFII) used in Example 1. They were evaluated in the same manner as in Example 1 and the results obtained were shown in Table 1.

### (1) Example 2

Deposition conditions of the host (PYI); 4 nm/sec

Deposition conditions of the dopant (AFII); 0.2 nm/sec thickness 40 nm ((PYI):(AFII)=40:2)

### (2) Example 3

Deposition conditions of the host (ANI); 4 nm/sec

Deposition conditions of the dopant (AFI); 0.2 nm/sec thickness 40 nm ((ANI):(AFI)=40:2)

### (3) Example 4

Deposition conditions of the host (PYI); 4 nm/sec

Deposition conditions of the dopant (AFI); 0.2 nm/sec thickness 40 nm ((PYI):(AFI)=40:2)

### Comparative Examples 1 to 10

In Comparative examples 1 to 10, organic EL devices were fabricated in the same manner as in Example 1 except that the following materials were used for an emitting layer instead of the host (ANI) and the dopant (AFII) used in Example 1. They were evaluated in the same manner as in Example 1 and the results obtained were shown in Table 1.

### (1) Comparative Example 1

Deposition conditions of the host (DPY); 4 nm/sec

Deposition conditions of the dopant (AFI); 0.2 nm/sec thickness 40 nm ((DPY):(AFI)=40:2)

### (2) Comparative Example 2

Deposition conditions of the host (TPB3); 4 nm/sec

Deposition conditions of the dopant (AFI); 0.2 nm/sec thickness 40 nm ((TPB3):(AFI)=40:2)

### (3) Comparative Example 3

Deposition conditions of the host (ANI); 4 nm/sec

Deposition conditions of the dopant (BDI); 0.2 nm/sec thickness 40 nm ((ANI):(BDI)=40:2)

### (4) Comparative Example 4

Deposition conditions of the host (ANI); 4 nm/sec

Deposition conditions of the dopant (BDII); 0.2 nm/sec thickness 40 nm ((ANI):(BDII)=40:2)

### (5) Comparative Example 5

Deposition conditions of the host (PYI); 4 nm/sec

Deposition conditions of the dopant (BDI); 0.2 nm/sec thickness 40 nm ((PYI):(BDI)=40:2)

### (6) Comparative Example 6

Deposition conditions of the host (PYI); 4 nm/sec.

Deposition conditions of the dopant (BDII); 0.2 nm/sec thickness 40 nm ((PYI):(BDII)=40:2)

### (7) Comparative Example 7

Deposition conditions of the host (ANII); 4 nm/sec

Deposition conditions of the dopant (AFI); 0.2 nm/sec thickness 40 nm ((ANII):(AFI)=40:2)

### (8) Comparative Example 8

Deposition conditions of the host (ANII); 4 nm/sec

Deposition conditions of the dopant (AFII); 0.2 nm/sec thickness 40 nm ((ANII):(AFII)=40:2)

### (9) Comparative Example 9

Deposition conditions of the host (PYII); 4 nm/sec

Deposition conditions of the dopant (AFII); 0.2 nm/sec thickness 40 nm ((PYII):(AFII)=40:2)

### (10) Comparative Example 10

Deposition conditions of the host (PYII); 4 nm/sec

Deposition conditions of the dopant (AFI); 0.2 nm/sec thickness 40 nm ((PYII):(AFI)=40:2)

TABLE 1

| | Color | Voltage (V) | Lifetime (h) |
|---|---|---|---|
| Example 1 | blue | 6.3 | 520 |
| Example 2 | blue | 5.8 | 280 |
| Example 3 | blue | 6.3 | 420 |
| Example 4 | blue | 5.8 | 220 |
| Comparative Example 1 | blue | 6.0 | 60 |
| Comparative Example 2 | blue | 6.2 | 150 |
| Comparative Example 3 | blue | 7.0 | 450 |
| Comparative Example 4 | blue | 7.2 | 350 |
| Comparative Example 5 | blue | 6.6 | 260 |
| Comparative Example 6 | blue | 6.7 | 200 |
| Comparative Example 7 | blue | 6.2 | 250 |
| Comparative Example 8 | blue | 6.0 | 280 |
| Comparative Example 9 | blue | 5.7 | 180 |
| Comparative Example 10 | blue | 5.8 | 160 |

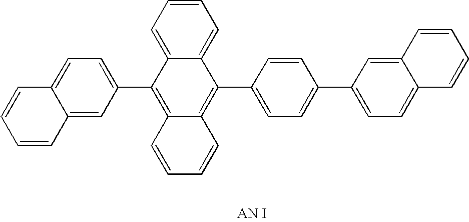

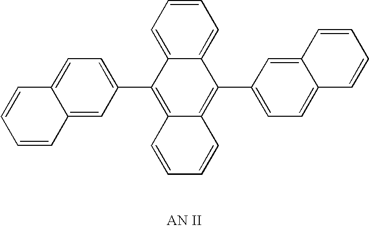

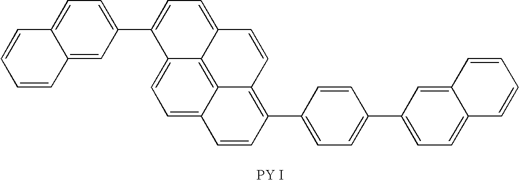

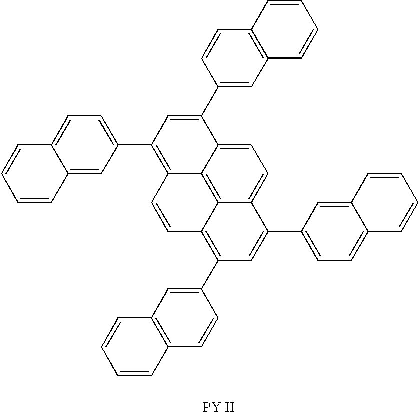

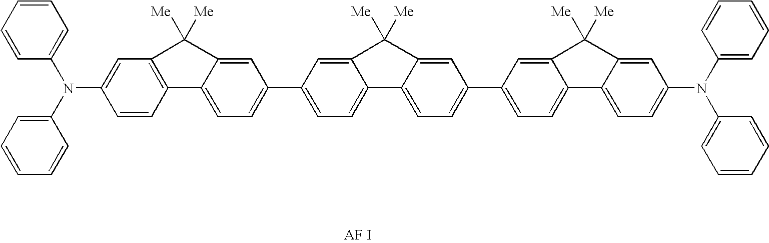

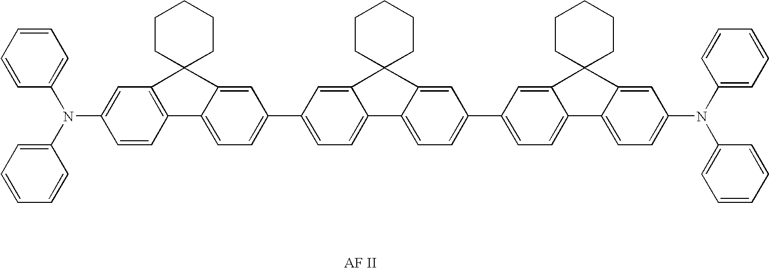

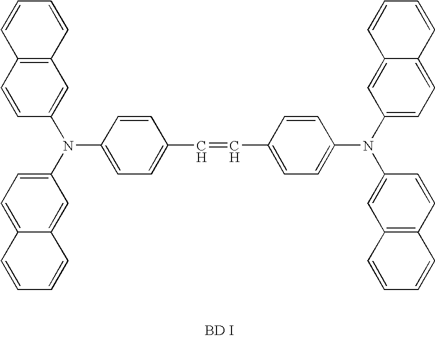

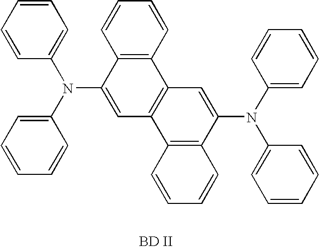

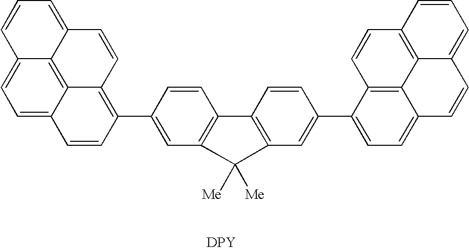

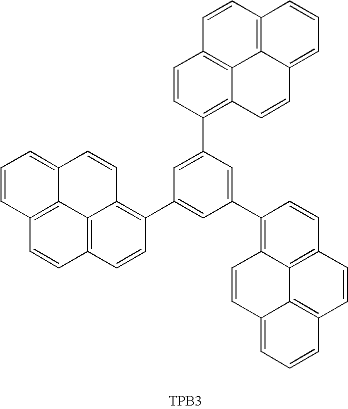

### INDUSTRIAL APPLICABILITY

The organic EL device of the invention can be applied to various displays such as displays for consumer and industrial use, specifically, a cellular phone, PDA, an automobile navigation system, a display monitor, TV, etc.

What is claimed is:

1. An organic electroluminescent device comprising a pair of electrodes and an emitting layer provided between the pair of electrodes,
the emitting layer comprising a derivative having an unsymmetrically substituted anthracene as a partial structure and an amine derivative represented by Formula (1), 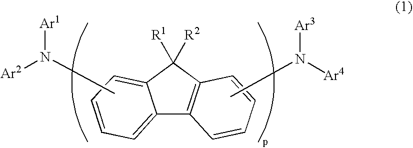
wherein Ar¹ to Ar⁴ are independently a substituted or unsubstituted aromatic ring having 6 to 50 nucleus carbon atoms, R¹ and R² may be the same or different substituents and linked to each other to form a saturated or unsaturated ring, and p is an integer of 1 to 6.

2. An organic electroluminescent device comprising a pair of electrodes and an emitting layer provided between the pair of electrodes,
the emitting layer comprising a derivative having an unsymmetrically substituted pyrene as a partial structure, the number of pyrene skeleton contained in the derivative being one, and an amine derivative represented by Formula (1), 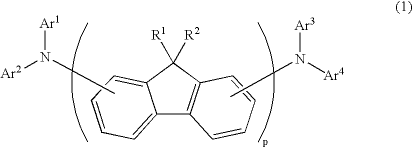
wherein Ar¹ to Ar⁴ are independently a substituted or unsubstituted aromatic ring having 6 to 50 nucleus carbon atoms, R¹ and R² may be the same or different substituents and linked to each other to form a saturated or unsaturated ring, and p is an integer of 1 to 6.

3. The organic electroluminescent device according to claim 1, wherein the amine derivative is a diaminofluorene derivative where R¹ and R² are linked to each other to form a saturated or unsaturated ring in Formula (1).

4. The organic electroluminescent device according to claim 2, wherein the amine derivative is a diaminofluorene derivative where R¹ and R² are linked to each other to form a saturated or unsaturated ring in Formula (1).

5. The organic electroluminescent device according to claim 1, wherein the amine derivative is contained in an amount of 0.1 to 20 mol % in the emitting layer.

6. The organic electroluminescent device according to claim 2, wherein the amine derivative is contained in an amount of 0.1 to 20 mol % in the emitting layer.

7. The organic electroluminescent device according to claim 3, wherein the amine derivative is contained in an amount of 0.1 to 20 mol % in the emitting layer.

8. The organic electroluminescent device according to claim 4, wherein the amine derivative is contained in an amount of 0.1 to 20 mol % in the emitting layer.
